(19) United States
(12) Patent Application Publication
(10) Pub. No.: US 2004/0037107 A1
(43) Pub. Date: Feb. 26, 2004

(54) Semiconductor storage device including random access memory cells having a plurality of indendently accessible access ports

(75) Inventor: Hideto Matsuoka, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/367,914

(22) Filed: Feb. 19, 2003

(30) Foreign Application Priority Data
Aug. 26, 2002 (JP) 2002-245025

(51) Int. Cl. G11C 11/24

(52) U.S. Cl. 365/149

(57) ABSTRACT

A dual port DRAM cell of a memory cell array circuit (110) has two ports, each connected to a bit line. The bit line is of open-bit-line configuration and is connected to a sense amplifier. An access circuit (150A) and an access circuit (150B) access to memory cells via one port and the other port, respectively. When the access circuit (150A) accesses to the memory cell, the sense amplifier amplifies the potential of the bit line connected to the access-object cell. During this amplification period, the access circuit (150A) outputs a control signal (WLONA). The access circuit (150B) receives the control signal (WLONA) and operates so as not to change, during the amplification period, the potential of a bit line adjacent to the bit line that is in the amplification period and is used by the access circuit (150B) at the time of access.

### BACKGROUND OF THE INVENTION

1. Field of the Invention

The present invention relates to a semiconductor storage device including random access memory cells having a plurality of independently accessible access ports and, in particular, to a technique for preventing unreliable and instable operations due to crosstalk noise between adjacent bit lines, or unreliable and instable operations due to data collision in write object memory cells. The present invention also relates to a technique for avoiding that the polarity of data depends on a port to be accessed, even when bit lines of the above-mentioned semiconductor storage device are twisted.

2. Description of the Background Art

A semiconductor memory cell having two input/output terminals (ports) that can independently perform read operation and write operation (hereinafter referred to as a “memory cell” or “cell”) is called for example “dual port memory cell.” As an example, a memory cell 600 of a dual port SRAM (static random access memory) will be described by referring to a circuit diagram in FIG. 24.

In the dual port SRAM cell 600, data can be inputted to and outputted from bit lines BL0 and ZBL0 via access transistors 601 and 601Z, respectively, and data can also be inputted to and outputted from bit lines BL1 and ZBL1 via access transistors 602 and 602Z, respectively. The gates of the access transistors 601 and 601Z are connected to a word line WL0, and the gates of the access transistors 602 and 602Z are connected to a word line WL1.

However, the dual port SRAM cell 600 is at a disadvantage in increasing capacity because it requires eight transistors per bit, as shown in FIG. 24. For this reason, there has been proposed a dual port DRAM that is smaller than the dual port SRAM 600 and uses DRAM (dynamic random access memory) cells.

FIG. 25 is a circuit diagram of a dual port DRAM cell 10. The dual port DRAM cell 10 has such a configuration made by combining two general DRAM cells, each of which is a single port DRAM cell configured by one transistor and one capacitor. Specifically, the storage node (charge hold terminal) SN of the capacitors 13 and that of the capacitor 14 are connected to each other (connected in common). The dual port DRAM cell 10 is configured by two transistors 11 and 12, and the capacitor 13 (or 14). The storage node SN of the capacitor 13 (or 14) is connected via the transistors 11 and 12 to bit lines BL0 and BL1, respectively. The gates of the transistors 11 and 12 are connected to word lines WL0 and WL1, respectively. In FIG. 25, the character “CP” denotes a cell plate of the capacitors 13 and 14. The dual port DRAM cell 10 has two ports A and B that correspond to the transistors 11 and 12, respectively. The dual port DRAM cell 10 is independently accessible to the ports A and B.

The dual port DRAM cell 10, independently accessible to the ports A and B, suffers from the following problem. That is, in the case that before a low voltage read by the bit line BL0 or BL1 of one port A or port B is amplified by a sense amplifier, the potential of the bit line BL1 or BL0 of the other port B or A is changed for example by write operation, the dual port DRAM cell 10 is subject to crosstalk noise between the bit lines BL0 and BL1, thereby destroying the data of the cell 10.

Such destruction of data will be described by referring to a conventional first dual port DRAM 700 using the dual port DRAM cell 10. Referring to FIG. 26, in the dual port DRAM 700, a memory cell array circuit includes a plurality of dual port DRAM cells 10 and sense amplifiers 30A and 30B. A peripheral circuit related to the operation of the memory array circuit includes a row decoder or row address selection means 751A and 751B, and a column decoder or column address selection means 752A and 752B. The row decoder 751A and column decoder 752A select a dual port DRAM cell 10 that accesses from the port A side, and the data voltage of the selected dual port DRAM cell 10 is then amplified by the sense amplifier 30A for the port A. Likewise, the row decoder 751B and column decoder 752B select a dual port DRAM cell 10 that accesses from the port B side, and the data voltage of the selected dual port DRAM cell 10 is then amplified by the sense amplifier 30B for the port B.

In the dual port DRAM 700, data can be read and written via a bit line BL11 connected to a transistor 11. Independently of this, data can be read and written via a bit line BL12 connected to a transistor 12.

The dual port DRAM 700 of FIG. 26 has the so-called open-bit-line configuration. That is, as shown in FIG. 26, two bit lines BL11 connected to the sense amplifier 30A for the port A extend in opposite directions and are respectively connected to the ports A of the dual port DRAM cells 10. In other words, the sense amplifier 30A is positioned between the cell 10 connected to one bit line BL11 and the cell 10 connected to the other bit line BL11. This is true for two bit lines BL12 connected to the sense amplifier 30B for the port B.

The dual port DRAM 700 so configured tends to cause noise between the adjacent bit lines BL11 and BL12. The bit lines BL11 for the port A and the bit lines BL12 for the port B can independently be activated. Therefore, as shown in a timing chart of FIG. 27, in period of time TA, from when the word line WL11 connected to the transistor 11 for the port A is activated to read data into the bit line BL11 to when this data is amplified by the sense amplifier 30A, if the potential of the adjacent bit line BL12 varies, a potential difference ΔV outputted to the bit line BL11 (corresponding to the above-mentioned read data) will be destroyed by crosstalk noise.

To avoid such data destruction, there has been proposed a conventional second dual port DRAM 800 having the configuration of FIG. 28. Each dual port DRAM cell 20 of the dual port DRAM 800 includes two pieces of the above-mentioned cell 10 (see FIG. 26), each of which holds complementary data. These two cells 10 are connected to paired word lines WL11 and WL12. That is, the dual port DRAM cell 20 is configured by four transistors 11, 11, 12, 12, and two capacitors 13, 13. The dual port DRAM 800 includes row decoders 851A and 851B, and column decoders 852A and 852B, as in the DRAM 700 of FIG. 26, and further includes input/output circuits 854A and 854B.

Data can be read and written via bit lines BL1 and BL3 connected to ports A of the two transistors 11, respectively. Also, data can be read and written via bit lines BL2 and BL4 connected to ports B of the two transistors 12, respectively.

The dual port DRAM 800 of FIG. 28 has the so-called folded-bit-line configuration. Specifically, as shown in FIG. 28, the complementary bit lines BL1 and BL3 connected to the sense amplifier 30A for the port A extend in the same direction. This is true for the complementary bit lines BL2 and BL4 connected to the sense amplifier 30B for the port B. Therefore, noise etc. that the word lines WL11, WL12, etc. apply to the bit lines BL1 to BL4 are cancelled by the complementary bit line pairs. In addition, noise between the adjacent bit lines, which may occur in the dual port DRAM 700 of FIG. 26, can be cancelled by twisting the bit lines BL1 and BL3 in order to change columns, as shown in FIG. 28.

However, twisting the bit lines BL1 and BL3 causes the following problem. Firstly, in the cells 20 locating in the first and second rows, data are outputted to the bit lines BL1 and BL3 when the word line WL11 is activated, and data are outputted to the bit lines BL2 and BL4 when the word line WL12 is activated. In the cells 20 locating in the third and fourth rows, data are outputted to the bit lines BL3 and BL1 when the word line WL11 is activated, and data are outputted to the bit lines BL2 and BL4 when the word line WL12 is activated. At this time, since the two cells 10 of the dual port DRAM 20 hold the complementary data, as described above, the bit lines BL1 and BL2 in the cells 20 locating in the first and second rows have the same polarity, whereas the bit lines BL1 and BL2 in the cells 20 locating in the third and fourth rows have different polarities. This is true for the bit lines BL3 and BL4. For example, when “0” is stored in the cell 20 locating in the third row, “0” is outputted to the bit line BL2 via the port B, whereas “1” is outputted to the bit line BL1 via the port A. Thus, different data are obtained depending on whether the port A or B is accessed with respect to a single cell 20. That is, a row address at which the bit lines BL1 and BL3 are twisted divides a region where the data of the port A agree the data of the port B from a region where they disagree.

Further, since the area of a single cell 20 of the dual port DRAM 800 in FIG. 28 equals two times the area of a single cell 10 in FIG. 26, the DRAM 800 has the problem that its integration degree is lower than that of the DRAM 700.

Furthermore, the dual port DRAM 800 has the following problem. Since a plurality of cells 20 having the same row address are connected to the individual word lines WL11 and WL12, data will collide between the ports A and B via the memory cells 20, when the two word lines WL11 and WL12 are activated concurrently. Such disadvantage can occur in the dual port DRAM 700. This problem will be described by taking as example the DRAM 800 of FIG. 28.

In the DRAM 800 of FIG. 28, when performing read operation via both of the ports A and B, even if, for example, the word lines WL11 and WL12 locating in the second row are activated concurrently, the data or data signal of the cell 20 is reliably amplified by sense amplifiers 30A and 30B, without causing any problem.

However, a problem occurs when the either or both of the ports A and B perform write operation. For example, consider the case that with respect to two cells 20 locating in the second row and holding “0”, data “0” is read via the port A of one cell 20 and, at the same time, data “1” is written via the port B of the other cell 20.

In this case, when the word lines WL11 and WL12 in the second row are activated concurrently, not only the port A but also the port B that is not the access object is opened in the aforesaid one cell 20. Likewise, the port A that is not the access object is opened in the aforesaid the other cell 20. As the result, with respect to the individual cells 20, data “0” is amplified by the sense amplifiers 30A and 30B. Thereafter, data “1” is written onto the sense amplifier 30B of the aforesaid the other cell 20 by the input/output circuit 854B. That is, in the aforesaid the other cell 20, the sense amplifier 30A for the port A holds “0”, whereas the sense amplifier 30B for the port B holds “1”. At this time, since the sense amplifier 30A for the port A and the sense amplifier 30B for the port B are connected via the cells 20, the data of the sense amplifiers 30A and 30B collide, thereby failing to perform normal write operation.

### SUMMARY OF THE INVENTION

It is an object of the present invention to provide a semiconductor storage device capable of preventing unreliable and instable operations due to crosstalk noise between adjacent bit lines, or preventing unreliable and instable operations due to data collision in write object memory cells.

According to a first aspect of the present invention, a semiconductor storage device includes a plurality of unit circuits, and a peripheral circuit connected to the plurality of unit circuits. Each of the plurality of unit circuits includes a plurality of first and second sense amplifiers, a plurality of first and second bit lines, and a plurality of random access memory cells. The plurality of first and second bit lines are connected to the plurality of first and second sense amplifiers, respectively, so as to make an open-bit-line configuration. Each of random access memory cell has first and second access transistors connected in series between paired first and second bit lines, and a capacitor connected to the first and second access transistors. In the plurality of unit circuits, the plurality of first and second bit lines are alternately disposed. The peripheral circuit includes a first access circuit and a second access circuit. The first access circuit is configured such that reading and writing of data to the plurality of random access memory cells are executable via the plurality of first bit lines. The second access circuit is configured such that reading and/or writing of data to the plurality of random access memory cells are executable via the plurality of second bit lines. The first or second access circuit includes a control signal generation circuit configured so as to output a control signal in response to an amplification period in which a first or second sense amplifier amplifies the potential of the first or second bit line. The second or first access circuit receives the control signal and operates so as not to change the potential of a second or first bit line connected to the first or second bit line in the amplification period via a random access memory cell.

The second or first access circuit operates so as not to change the potential of the second or first bit line connected to the first or second bit line in the amplification period via the random access memory cell, during the amplification period. Therefore, even when the first and second bit lines are alternately disposed and make the open-bit-line configuration, crosstalk noise between the adjacent bit lines is avoidable. This leads to the elimination of data destruction due to crosstalk noise.

According to a second aspect of the present invention, a semiconductor storage device includes a plurality of unit circuits, and a peripheral circuit connected to the plurality of unit circuits. Each of the plurality of unit circuits includes a random access memory cell, first and second bit lines, and a word line group. The random access memory cell has first and second ports and first and second control terminals that control accesses via the first and second ports, respectively. The first and second bit lines are connected to the first and second ports, respectively. The word line group has first and second word lines connected to the first and second control terminals, respectively. The plurality of word line groups are connected in common among the plurality of unit circuits. The peripheral circuit includes a first access circuit, a second access circuit, and a judgment circuit. The first access circuit is configured such that reading and writing of data to each random access memory cell are executable via the first bit line. The second access circuit is configured such that reading and/or writing of data to the each random access memory cell are executable via the second bit line. The judgment circuit acquires information of access-object cells that become access objects of the first and second access circuits among a plurality of random access memory cells, and judges whether the access-object cells are connected to the same word line group. The semiconductor storage device further includes a first write support circuit. The first write support circuit is controlled based on the result of judgment made by the judgment circuit when the first access circuit performs the writing of the data. If configured such that the second access circuit can execute the writing, the semiconductor storage device further includes a second write support circuit. The second write support circuit is controlled based on the result of judgment made by the judgment circuit when the second access circuit performs the writing of the data.

When the access-object cells are connected to the same word line group, the use of the write support circuit enables to prevent data collision in the access-object cells performing write operation (i.e., write-object cells).

According to a third aspect of the present invention, a semiconductor storage device includes a plurality of unit circuits, and a peripheral circuit connected to the plurality of unit circuits. Each of the plurality of unit circuits includes a random access memory cell, first and second bit lines, and a word line group. The random access memory cell has first and second ports and first and second control terminals that control accesses via the first and second ports, respectively. The first and second bit lines are connected to the first and second ports, respectively. The word line group has first and second word lines connected to the first and second control terminals, respectively. The peripheral circuit includes a first access circuit and a second access circuit. The first access circuit is configured such that reading and writing of data to each random access memory cell are executable via the first bit line. The second access circuit configured such that reading and/or writing of data to the each random access memory cell are executable via the second bit line. The plurality of unit circuits are divided into a plurality of blocks so as to include at least one unit circuit, the word line groups are not connected in common among the plurality of blocks. The semiconductor storage device further includes a plurality of selection circuits disposed in the plurality of blocks, respectively. Each of the plurality of selection circuits is configured so as to selectively activate, only when an access-object cell that becomes access object of the first or second access circuit is present in the corresponding block, the first or second word line of the at least one unit circuit in the corresponding block.

The word line groups are not connected in common among the plurality of blocks, and the selection circuit is disposed per block. Therefore, when the first and second access circuits access to the random access memory cells in different blocks, the first and second word lines in a single block cannot be concurrently activated. Even when the first or second access circuit performs writing, it is avoidable that data collide via the access-object cells (i.e., write-object cells), which can occur if data are different before and after writing.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram to explain a semiconductor storage device according to a first preferred embodiment of the present invention;

FIG. 2 is a circuit diagram to explain a memory cell array circuit of the semiconductor storage device of the first preferred embodiment;

FIG. 3 is a circuit diagram to explain a unit column circuit of the semiconductor storage device of the first preferred embodiment;

FIG. 4 is a timing chart to explain the operation of the semiconductor storage device of the first preferred embodiment;

FIG. 5 is a circuit diagram to explain a control signal generation circuit and a timing delay circuit in the semiconductor storage device of the first preferred embodiment;

FIG. 6 is a circuit diagram to explain other control signal generation circuit of the semiconductor storage device of the first preferred embodiment;

FIG. 7 is a block diagram to explain a semiconductor storage device according to a second preferred embodiment of the present invention;

FIG. 8 is a circuit diagram to explain a unit column circuit of the semiconductor storage device of the second preferred embodiment;

FIG. 9 is a circuit diagram to explain a data inverter of the semiconductor storage device of the second preferred embodiment;

FIG. 10 is a block diagram to explain a semiconductor storage device according to a third preferred embodiment of the present invention;

FIGS. 11 and 12 are circuit diagrams to explain a memory cell array circuit of the semiconductor storage device of the third preferred embodiment;

FIG. 13 is a timing chart to explain the operation of the semiconductor storage device of the third preferred embodiment;

FIG. 14 is a circuit diagram to explain a column selection signal generation circuit of the semiconductor storage device of the third preferred embodiment;

FIG. 15 is a block diagram to explain a semiconductor storage device according to a fourth preferred embodiment of the present invention;

FIGS. 16 and 17 are circuit diagrams to explain a memory cell array circuit of the semiconductor storage device of the fourth preferred embodiment;

FIG. 18 is a block diagram to explain a sense amplifier activation signal generation circuit of the semiconductor storage device of the fourth preferred embodiment;

FIG. 19 is a block diagram to explain a semiconductor storage device according to a fifth preferred embodiment of the present invention;

FIGS. 20 and 21 are circuit diagrams to explain a memory cell array circuit of the semiconductor storage device of the fifth preferred embodiment;

FIG. 22 is a circuit diagram to explain a row selection circuit activation signal generation circuit of the semiconductor device storage device of the fifth preferred embodiment;

FIG. 23 is a block diagram to explain a sense amplifier activation signal generation circuit of the semiconductor storage device of the fifth preferred embodiment;

FIG. 24 is a circuit diagram to explain a dual port SRAM cell;

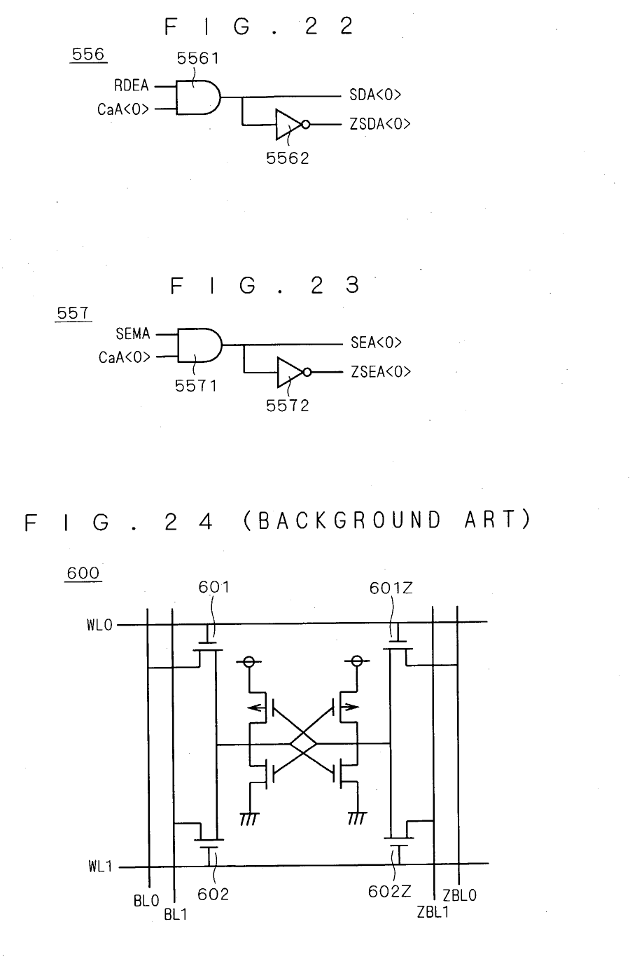

FIG. 25 is a circuit diagram to explain a dual port DRAM cell;

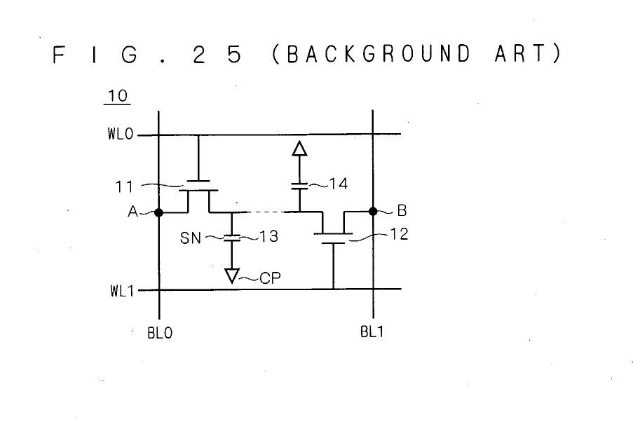

FIG. 26 is a circuit diagram to explain a conventional first dual port DRAM;

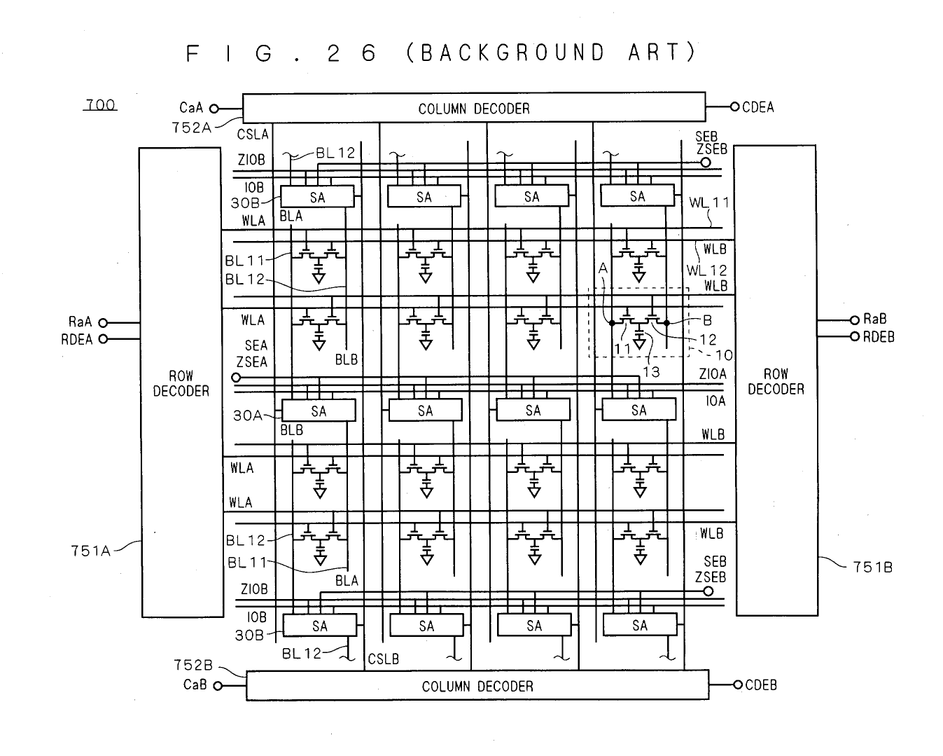

FIG. 27 is a timing chart to explain the operation of the conventional first dual port DRAM; and

FIG. 28 is a circuit diagram to explain a conventional second dual port DRAM.

### DESCRIPTION OF THE PREFERRED EMBODIMENTS

First Preferred Embodiment

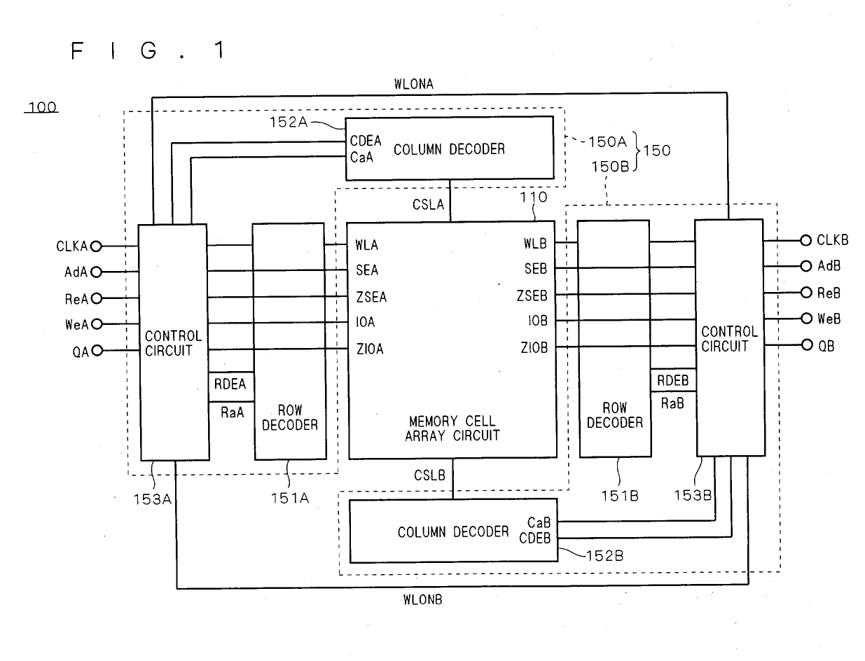

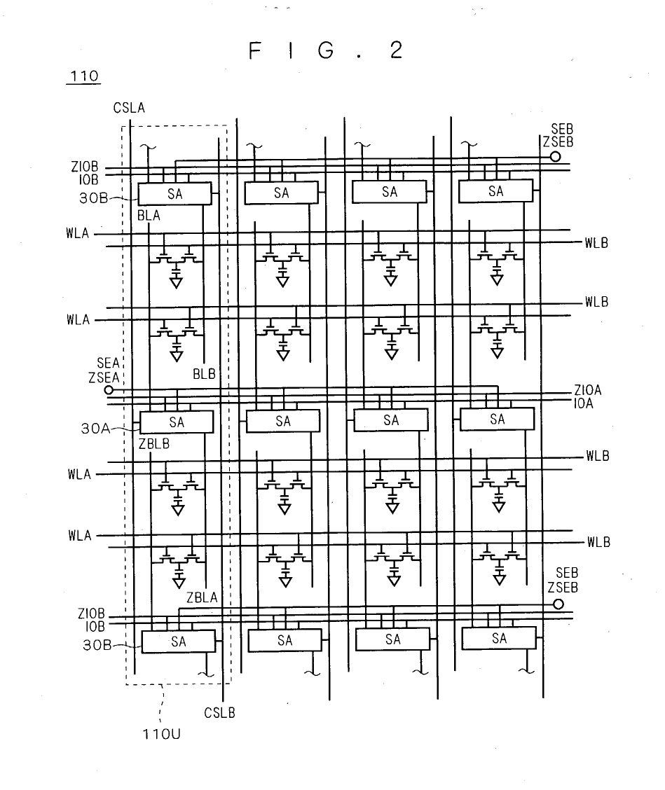

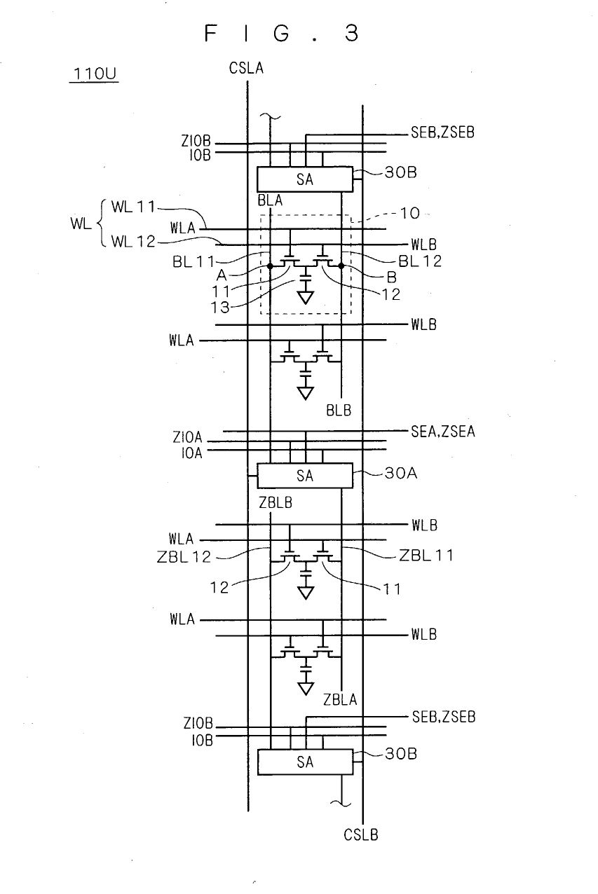

FIG. 1 is a block diagram to explain a dual port DRAM (dynamic random access memory) 100, as a semiconductor storage device according to a first preferred embodiment. FIG. 2 is a circuit diagram to explain a memory cell array circuit 110 of the dual port DRAM 100. FIG. 3 is a circuit diagram to explain a unit column circuit (hereinafter referred to as a “unit circuit”) 110U of the memory cell array circuit 110.

Referring to FIG. 1, the dual port DRAM 100 is roughly classified into the memory cell array circuit 110 and a peripheral circuit 150 connected to the memory cell array circuit 110. The peripheral circuit 150 includes two access circuits 150A and 150B, each of which is accessible to individual dual port DRAM cells 10 (see FIG. 3) in the memory cell array circuit 110.

Referring to FIG. 2, the memory cell array circuit 110 includes, for example, four unit circuits 110U. The unit circuit 110U will be described by referring to FIG. 3.

The unit circuit 110U includes a dual port DRAM cell (hereinafter also referred to simply as a “cell”) 10, sense amplifiers 30A and 30B, bit lines BL11, ZBL11, BL12, and ZBL12, and a word line group WL (including word lines WL11 and WL12). In the figures, the character “SA” designates the sense amplifiers.

Two access transistors 11 and 12, each of which is formed by an MOSFET, and a capacitor 13, configure the dual port DRAM cell 10. Specifically, one terminal (source) of each of the access transistors 11 and 12 is connected to one terminal (charge hold terminal, i.e., storage node) of the capacitor 13. The other terminals of the access transistors 11 and 12 (hereinafter also referred to as “input/output terminals A and B” or “ports A and B”) are connected to paired bit lines BL 11 and BL12 or paired bit lines ZBL11 and ZBL12, respectively. At this time, the two access transistors 11 and 12 are connected in series between the paired bit lines BL11 and BL12, or between the paired bit lines ZBL11 and ZBL12. The gates of the access transistors 11 and 12 are connected to the word lines WL11 and WL12, respectively.

In the unit circuit 110U, the complementary bit lines BL11 and ZBL11 are connected to the sense amplifier 30A, and the complementary bit lines BL12 and ZBL12 are connected to the sense amplifier 30B. To the individual sense amplifier 30A, the two bit lines BL11 and ZBL11 are connected so as to make an open-bit-line configuration. That is, the two bit lines BL11 and ZBL11 extend in the opposite directions from the sense amplifier 30A. Likewise, the sense amplifier 30B and bit lines BL12 and ZBL12 are connected so as to make an open-bit-line configuration. Owing to this style of connection, the sense amplifiers 30A and 30B are alternately disposed. In the memory cell array circuit 110, the bit lines BL11 and BL12, and the bit lines ZBL11 and ZBL12 are alternately disposed in the array direction of the unit circuits 110U.

Although FIG. 3 illustrates the case that the two dual port DRAM cells 10 are connected between the paired bit lines BL11 and BL12, and between the paired bit lines ZBL11 and ZBL12, the number of the dual port DRAM cells 10 may be one or not less than three.

In the following, similar reference numerals or characters are basically used to denote similar elements, such as sense amplifiers 30A and 30B, and word line activation signals WLA and WLB to be described later, wherein character “A” appended to the end of the reference numerals denotes an element related to the access circuit A and the port A, and character “B” denotes an element related to the access circuit B and the port B.

In the dual port DRAM cell 10, charge and discharge of the capacitor 13 are. performed via the access transistors 11 and 12, namely the ports A and B, thereby performing data writing and reading. On/off controls of the access transistors 11 and 12 are executed by applying word line activation signals WLA and WLB to the word lines WL11 and WL12, respectively. By independently applying the word line activation signals WLA and WLB, the data reading and writing via the ports A and B can be executed independently.

In data read operation, signals or potentials BLA and ZBLA that have been applied via the ports A to the bit lines BL11 and ZBL11 are amplified by the sense amplifier 30A and then read into the access circuit 150A, as signals or data IOA and ZIOA, respectively. Likewise, signals or potentials BLB and ZBLB applied via the ports B to the bit lines BL12 and ZBL12 are amplified by the sense amplifier 30B and then read into the access circuit 150B, as signals or data IOB and ZIOB, respectively.

In data write operation, data is written onto the dual port DRAM cell 10 via the bit lines BL11 and ZBL11 and the ports A, by writing signals or data IOA and ZIOA onto the sense amplifier 30A. Likewise, data is written onto the dual port DRAM cell 10 via the bit lines BL12 and ZBL12 and the ports B, by writing signals or data IOB and ZIOB onto the sense amplifier 30B.

The sense amplifier 30A is activated by sense amplifier activation signals SEA and ZSEA, and the sense amplifier 30B is activated by sense amplifier activation signals SEB and ZSEB. A column selection signal CSLA controls the connection via the sense amplifier 30A between the bit lines BL11, ZBL11 and the signal lines or data lines of the signals IOA, ZIOA. A column selection signal CSLB controls the connection via the sense amplifier 30B between the bit lines BL12, ZBL12 and the signal lines or data lines of the signals IOB, ZIOB. The column selection signal CSLA is applied concurrently to all of a plurality of sense amplifiers 30A in the unit circuit 110U. This is true for the column selection signal CSLB.

Referring to FIG. 2, in the memory cell array circuit 110, the word lines WL11 of the corresponding dual port DRAM cells 10 between the unit circuits 110U are connected to form a single line. This is true for the word lines WL12. Word line activation signals WLA and WLB are applied in common to these corresponding dual port DRAM cells 10. It can be interpreted that the long word lines WL11 and WL12 in the entire memory cell array circuit 110 are obtained by connecting together (i.e., unifying) the word lines WL11 and WL12 per unit circuit 110U.

At this time, a plurality of dual port DRAM cells 10 connected to the same word lines WL11 and WL12 or the same word line group WL have the same row address, and a plurality of dual port DRAM cells 10 in each unit circuit 110U have the same column address. That is, each dual port DRAM cell 10 is specified by a combination of a row address and a column address, and is selected to enter the accessible state by a combination of the word line activation signal WLA or WLB and the column selection signal CSLA or CSLB.

The sense amplifier activation signals SEA and ZSEA are applied to all of the corresponding sense amplifiers 30A among a plurality of unit circuits 110U. This is true for the sense amplifier activation signals SEB and ZSEB. The corresponding sense amplifiers 30A share signal lines of signals IOA and ZIOA, as well as signal lines of signals IOB and ZIOB.

Returning to FIG. 1, the access circuit 150A includes a row decoder or row address selection means 151A, a column decoder or column address selection means 152A, and a control circuit 153A. The control circuit 153A receives a clock signal or synchronous signal CLKA and uses it in various operations.

When the access circuit 150A performs read operation, a read instruction (read enable signal) ReA and an address signal AdA of the dual port DRAM cell 10 that is access object (i.e., read object) are inputted to the control circuit 153A. Based on these, the control circuit 153A generates sense amplifier activation signals SEA, ZSEA and outputs these signals to the memory cell array circuit 110, the control circuit 153A also generates a row address signal RaA and word line activation signal RDEA and outputs these signals to the row decoder 151A, and the control circuit 153A also generates a column address signal CaA and column selection line activation signal CDEA and outputs these signals to the column decoder 152A. The row decoder 151A generates a word line activation signal WLA and outputs it to. the memory cell array circuit 110. The column decoder 152A generates a column selection signal CSLA and outputs it to the memory cell array circuit 110. Data IOA and ZIOA read from the dual port DRAM cell 10 are outputted via the control circuit 153A, as data QA.

When the access circuit 150A performs write operation, a write instruction (write enable signal) WeA, an address signal AdA of the dual port DRAM cell 10 that is access object (i.e., write object), and a write data Q are inputted to the control circuit 153A. Like the read operation, the control circuit 153A outputs sense amplifier activation signals SEA, ZSEA to the memory cell array circuit 110, the control circuit 153A also outputs a row address signal RaA and word line activation signal RDEA to the row decoder 151A, and the control circuit 153A also outputs a column address signal CaA and column selection line activation signal CDEA to the column decoder 152A. In addition, the control circuit 153A generates data IOA and ZIOA from the data QA, and outputs them to the memory cell array circuit 110. The row decoder 151 A and column decoder 152A output a word line activation signal WLA and column selection signal CSLA to the memory cell array circuit 110. As the result, data is written onto the dual port DRAM cell 10 as a write object.

The access circuit 150B includes a row decoder 151B, a column decoder 152B, and a control circuit 153B, and operates similarly to the above-mentioned access circuit 150A.

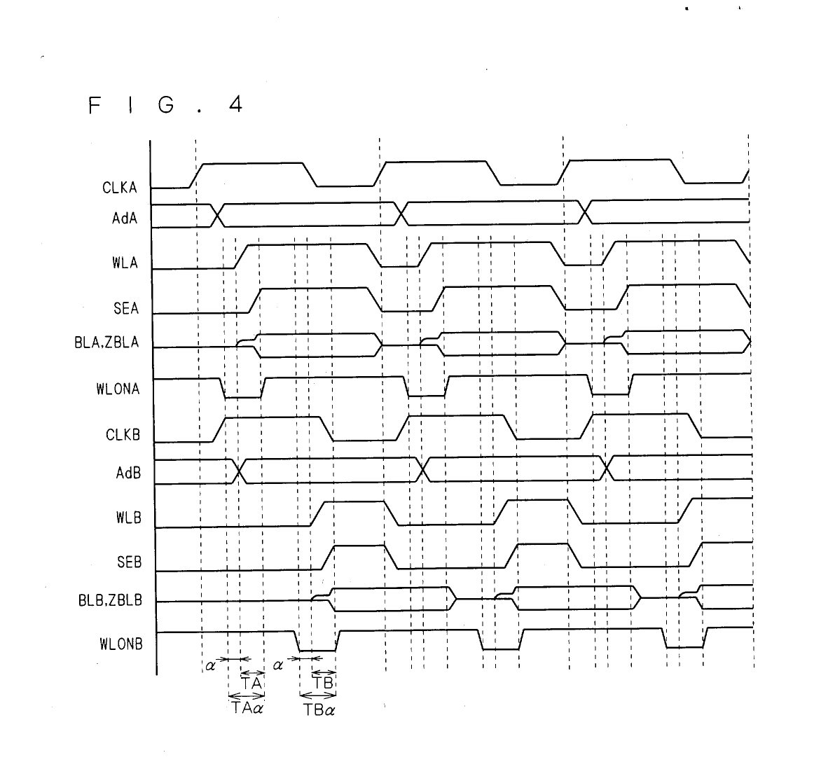

With this configuration, the access circuit 150A can perform data reading and writing to the desired one among a plurality of dual port DRAM cells 10 via the corresponding bit line BL11 or ZBL11. Likewise, the access circuit 150B can perform data reading and writing to the desired one among a plurality of dual port DRAM cells 10 via the corresponding bit line BL12 or ZBL12. Basically, the access circuits 150A and 150B are independently operable and they operate in accordance with the timing chart given in FIG. 4.

Referring to FIG. 4, during period TA, the potentials or signals BLA and ZBLA of bit lines BL11 and ZBL11 connected to the dual port DRAM cell 10 to which the access circuit 150A accesses are amplified by the corresponding sense amplifier 30A. Concretely, the amplification period TA is a period of time of from the rise of the word line activation signal WLA to the termination of the variations in potentials BLA and ZBLA of the bit lines BL11 and ZBL11. In the dual port DRAM 100, during the amplification period TA or a sense start period TA α (the sum of amplification period TA and period α of immediately before the period TA), namely at least during the amplification period TA, the access circuit 150B is configured so as not to change the potentials or the signals BLB and ZBLB of the bit lines BL12 and ZBL12 connected to the dual port DRAM cell 10 to which the access circuit 150A accesses.

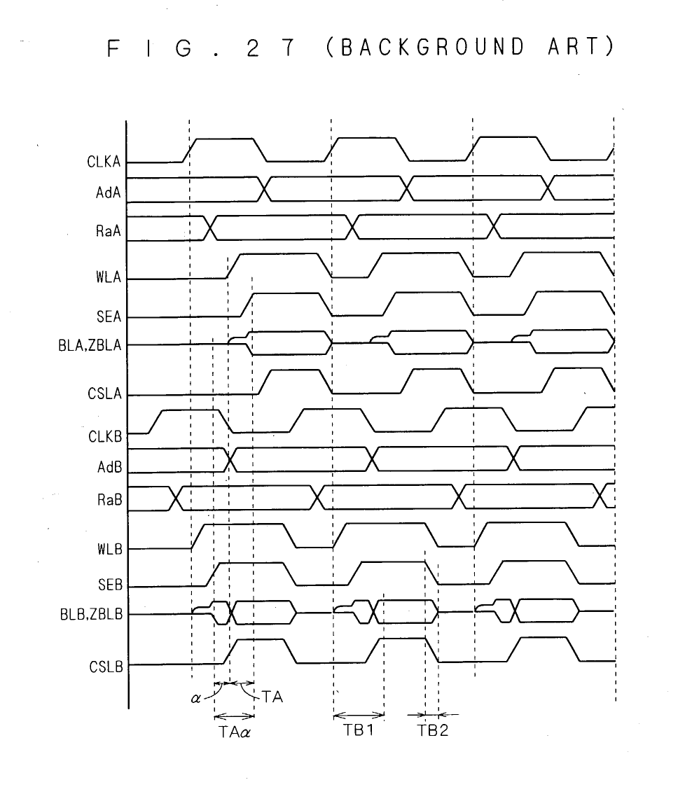

As described in connection with FIG. 27, the potentials BLB and ZBLB of the bit lines BL12 and ZBL12 change in period TB1 that is the sum of the sense start period and the period during which the potentials of the bit lines BL12 and ZBL12 are inverted at the time of writing, and the potentials BLB and ZBLB change in equalize period TB2 of the bit lines BL12 and ZBL12. Period TB1 starts when a word line activation signal WLB begins to rise, and period TB2 starts when the word line activation signal WLB begins to fall.

Therefore, the access circuit 150B delays the timings at which the word line activation signal WLB begins to rise and fall, so that period TA or TA α does not overlap with period TB1 and TB2. This avoids that the potentials BLB and ZBLB of the bit lines BL12 and ZBL12 change during period TA or TA α. Concretely, the access circuit 150B operates such that during period TA or TA α, the word line activation signal WLB is not changed with respect to the dual port DRAM cell 10 connected to the bit lines BL12 and ZBL12 that are respectively adjacent to the bit lines BL11 and ZBL11 of which potential is being amplified.

The column selection signal CSLB and the activation signals SEB and ZSEB of the sense amplifier 30B are generated based on the timing of the word line activation signal WLB. Therefore, the column selection signal CSLB and the sense amplifier activation signals SEB and ZSEB can be delayed in accordance with the delay of the word line activation signal WLB.

Similarly, the access circuit 150A also operates such that during the amplification period TB or the sense start period TB α with respect to the access circuit 150B, the activation signal WLA does not change with respect to the dual port DRAM cell 10 connected to the bit lines BL11 and ZBL11 that are respectively adjacent to the bit lines BL12 and ZBL12 of which potential is being amplified.

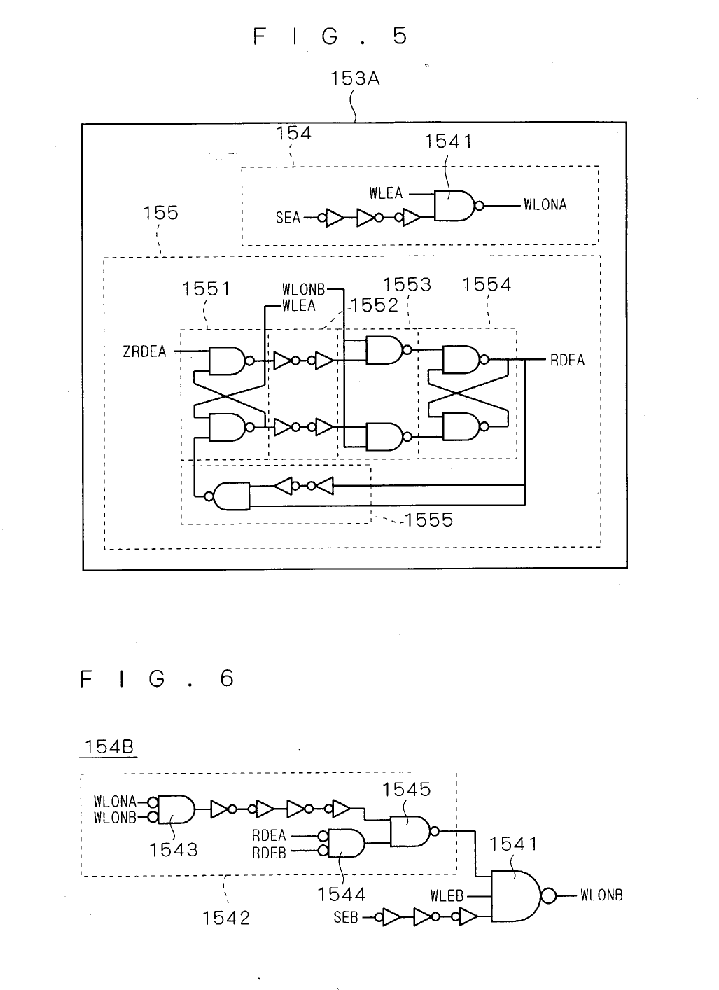

Such operation of the access circuit 150A is executable by a control signal generation circuit 154 and timing delay circuit 155, which are shown in FIG. 5 as example. Similar circuits are used for the access circuit 150B. The control signal generation circuit 154 and timing delay circuit 155 are disposed in the control circuit 153A of the access circuit 150A.

The control signal generation circuit 154, firstly, performs an NAND operation (NOT-AND operation) of a signal that is obtained by delaying the inverted signal of the sense amplifier activation signal SEA and a signal WLEA to be described later by an NAND circuit 1541, and then outputs the result as a control signal WLONA. Likewise, a control signal WLONB is generated by the control circuit 153B of the access circuit 150B. The control signals WLONA and WLONB are sent to the control circuits 153B and 153A of the access circuits 150B and 150A, respectively, as shown in FIG. 1, and then inputted to the timing delay circuit 155 in the control circuits 153B and 153A, respectively, as shown in FIG. 5.

In the timing delay circuit 155, a delay circuit 1552 composed of a plurality of NOT circuits or inverters, and an NAND circuit 1553 are connected in the order named between the output of an NAND flip-flop 1551 and the input of an NAND flip-flop 1554. An output signal of the rear-stage flip-flop 1554 corresponds to a word line activation signal RDEA of which timing is delayed. As previously described, the row decoder 151A generates a word line activation signal WLA based on the word line activation signal RDEA (see FIG. 1). The word line activation signal RDEA is delayed by the delay circuit 1555 and then inputted to the front-stage flip-flop 1551 together with a word line activation signal ZRDEA (to be generated in the control circuit 150A). Both of the signals RDEA and ZRDEA are not always complementary.

An output signal of the delay circuit 1552 and a control signal WLONB are inputted to the NAND circuit 1553. Therefore, when the control signal WLONB is “0”, i.e., during the sense start period TB α, the word line activation signal RDEA, namely the word line activation signal WLA, will not change (see FIG. 4).

The delay circuit 1555 outputs, via an NAND circuit, a word line activation signal RDEA and a signal RDEA that is obtained by delaying the word line activation signal RDEA by the NOT circuits. This delay circuit 1555 determines the activation period of the word line WL required at the time of reading and writing operations.

The output of the front-stage flip-flop 1551 corresponds to the aforesaid signal WLEA, and it is inputted to the control signal generation circuit 154 as described above. At this time, the control signal generation circuit 154 has only the NAND circuit between the input of the signal WLEA and the generation of the control signal WLONA. On the other hand, the timing delay circuit 155 has the circuits 1552, 1553, and 1554 between the input of the signal WLEA and the generation of the word line activation signal RDEA. In addition, there are some stages of circuits in order to obtain the word line activation signal WLA from the word line activation signal RDEA. Therefore, as shown in FIG. 4, after the control signals WLONA and WLONB transit, the word line activation signals WLA and WLB transit. Time deviation or time difference between the two transition timings corresponds to the above-mentioned period α. That is, period α is adjustable by the number of circuits to be disposed after the circuit to which the signals WLEA and WLEB are inputted.

Thus, the timing delay circuit 155 delays the operation timings of the access circuits 150A and 150B, more specifically, the timing at which there begins to change the potentials WLB and WLA of the word lines WL12 and WL11 connected to the dual port DRAM cell 10 having connections to the bit lines BL11, ZBL11, BL12, and ZBL12 in the amplification periods TA and TB. By doing so, it is avoidable that the above-mentioned potentials WLB and WLA change during the amplification periods TA and TB or during the sense start periods TA α and TB α.

Therefore, in the dual port DRAM 100, even if the bit lines BL11 and BL12 are alternately disposed and also make an open-bit-line configuration, crosstalk noise between the adjacent bit lines BL11 and BL12 is avoidable, thereby eliminating data destruction due to crosstalk noise.

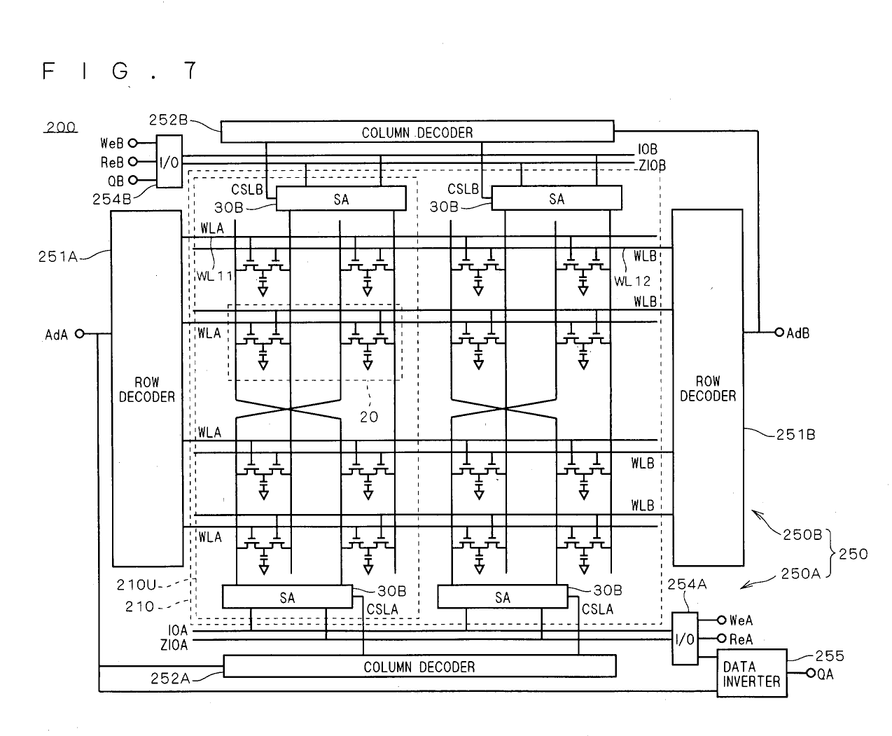

Meanwhile, it can be considered that period TA or TA α and period TB or TB α start at the same time. At this time, both of the control signals WLONA and WLONB become “0” at the same time. This is avoidable by replacing, for example, the control signal generation circuit 154 of the control circuit 153B with a control signal generation circuit 154B shown in FIG. 6. That is, the control signal generation circuit 154B can perform such an operation that the processing based on the control signal WLONA takes preference to the processing based on the control signal WLONB.

The control signal generation circuit 154B is obtainable by adding a circuit 1542 to the control signal generation circuit 154 of FIG. 5. The circuit 1542, firstly, performs an NOR operation (NOT-OR operation) of the control signals WLONA and WLONB by an NOR circuit 1543, and performs an NOR operation of the word line activation signals RDEA and RDEB by an NOR circuit 1544. Then, the circuit 1542 performs an NAND operation of a signal obtained by delaying the operation result of the NOR circuit 1543 and an output signal of the NOR circuit 1544 by an NAND circuit 1545. In the control signal generation circuit 154B, an NAND circuit 1541 obtains the operation result of the NAND circuit 1545, the signal WLEB, and the delayed inversion signal of the sense amplifier activation signal SEB. In an alternative, in place of the control signal generation circuit 154B, the same circuit as the circuit 154B may be added to the control circuit 153A.

Second Preferred Embodiment

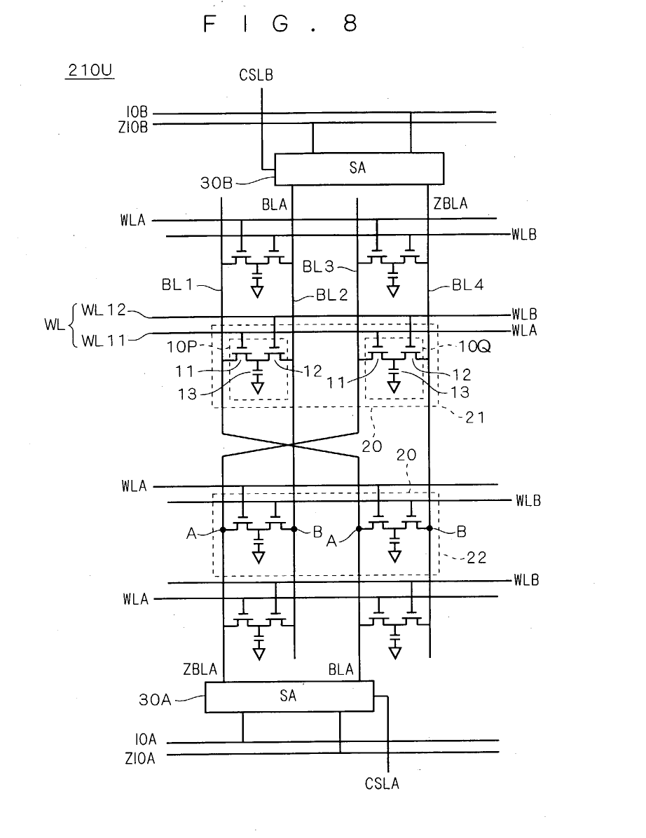

FIG. 7 is a circuit diagram to explain a dual port DRAM 200, as a semiconductor storage device according to a second preferred embodiment. As shown in FIG. 7, the dual port DRAM 200 is roughly classified into the memory cell array circuit 210 and a peripheral circuit 250 connected to the memory cell array circuit 210. The peripheral circuit 250 includes two access circuits 250A and 250B, each of which is accessible to individual dual port DRAM cells 20 in the memory cell array circuit 210.

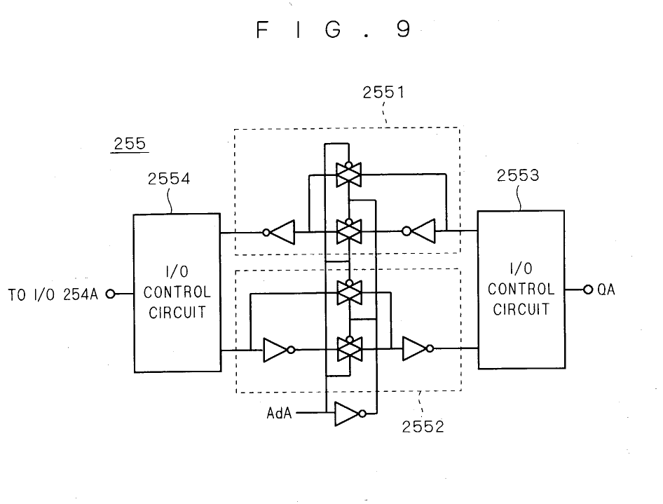

Referring to FIG. 7, the memory cell array circuit 210 includes, for example, two unit circuits 210U. The unit circuit 210U will be described by referring to FIG. 8.

The unit circuit 210U includes a dual port DRAM cell 20, sense amplifiers 30A and 30B, bit lines BL1, BL2, BL3, and BL4, and a word line group WL.

The dual port DRAM cell 20 includes two memory cells 10P and 10Q holding respective data complementary to each other. The memory cells 10P and 10Q have the same configuration as the above-mentioned dual port DRAM cell 10 (see FIG. 3). That is, the memory cells 10P and 10Q are respectively configured by two access transistors 11 and 12 connected to each other at their one ends, and a capacitor 13. The gates of the two access transistors 11 are connected to a word line WL11, and the gates of the two access transistors 12 are connected to a word line WL12.

FIG. 8 shows two dual port DRAM cells 20 that can roughly be classified into two blocks depending on the style of connection to the bit lines BL1, BL2, BL3, and BL4. In the dual port DRAM cell 20 that belongs to one block (hereinafter also referred to as a “dual port DRAM cell 21”), the two access transistors 11 and 12 of the memory cell 10P are connected in series between the bit lines BL1 and BL2, and the two access transistors 11 and 12 of the memory cell 10Q are connected in series between the bit lines BL3 and BL4. On the other hand, in the dual port DRAM cell 20 that belongs to the other block (hereinafter also referred to as a “dual port DRAM cell 22”), the two access transistors 11 and 12 of the memory cell 10P are connected in series between the bit lines BL3 and BL2, and the two access transistors 11 and 12 of the memory cell 10Q are connected in series between the bit lines BL1 and BL4. Therefore, as shown in FIG. 8, the bit lines BL1 and BL3 cross (in three dimensions) or twist.

The bit lines BL1 and BL3 are connected to a sense amplifier 30A so as to make the so-called folded-bit-line configuration. That is, the paired bit lines BL1 and BL3 extend in the same direction with respect to the sense amplifier 30A. Likewise, the bit liens BL2 and BL4 are connected to a sense amplifier 30B so as to form the folded-bit-line configuration.

The sense amplifier 30A inputs to and outputs from the bit lines BL1 and BL3 complementary data BLA and ZBLA, thereby writing and reading the data BLA and ZBLA via the ports A of the memory cells 10P and 10Q. Likewise, the sense amplifier 30B writes and reads data BLB and ZBLB via the bit lines BL2 and BL4, and the ports B of the memory cells 10P and 10Q. Further, the sense amplifier 30A is connected to signal lines of complementary input/output data IOA and ZIOA, and the sense amplifier 30B is connected to signal lines of complementary input/output data IOB and ZIOB. The signal lines of the data IOA, which are connected to the corresponding sense amplifiers 30A and 30B among a plurality of unit circuits 210U, are connected to form a single line. This is true for the signal lines ZIOA, IOB and ZIOB.

Although the dual port DRAM cells 20 and 21, two for each, are shown in FIG. 8, one or not less than three for each may be used.

Returning to FIG. 7, the access circuit 250A includes a row decoder 251A, column decoder 252A, input/output circuit (denoted by the symbol “I/O” in the figure) 254A, and data inverter 255.

The row decoder 251A, which is connected to word lines WL11, receives address AdA of a dual port DRAM cell 20 as access object, and applies a word line activation signal WLA to a predetermined word line WL11. The corresponding word lines WL11 are connected in order to apply word line activation signals WLA to all of the corresponding dual port DRAM cells 20 among a plurality of unit circuits 210U. This is true for the word lines WL12. The column decoder 252A, which is connected to sense amplifiers 30A, receives address AdA of a dual port DRAM cell 20 as access object, and outputs a column selection signal CSLA to a predetermined sense amplifier 30A. Thereby, the access circuit 250A performs data reading and writing to the dual port DRAM cell 20 via the bit lines BL1 and BL3.

The input/output circuit 254A is connected to signal lines of data IOA and ZIOA, while it is connected to the terminals of read enable signal ReA and write enable signal WeA, and one input/output terminal of the data inverter 255.

The data inverter 255 further has the other input/output terminal for data QA, and a terminal for receiving the address AdA of the dual port DRAM cell 20 as access object. The data inverter 255 inverts write data QA (i.e., “0”/“1” or “High”/“Low” of the data QA) based on the address AdA, and outputs it to the input/output circuit 254A. On the other hand, the data inverter 255 inverts data read via the input/output circuit 254A, based on the address AdA, and outputs it as read data QA. More specifically, the data of the dual port DRAM cell 21 that belongs to the above-mentioned one block is outputted without inverting, whereas the data of the dual port DRAM cell 22 that belongs to the above-mentioned the other block is inverted and outputted.

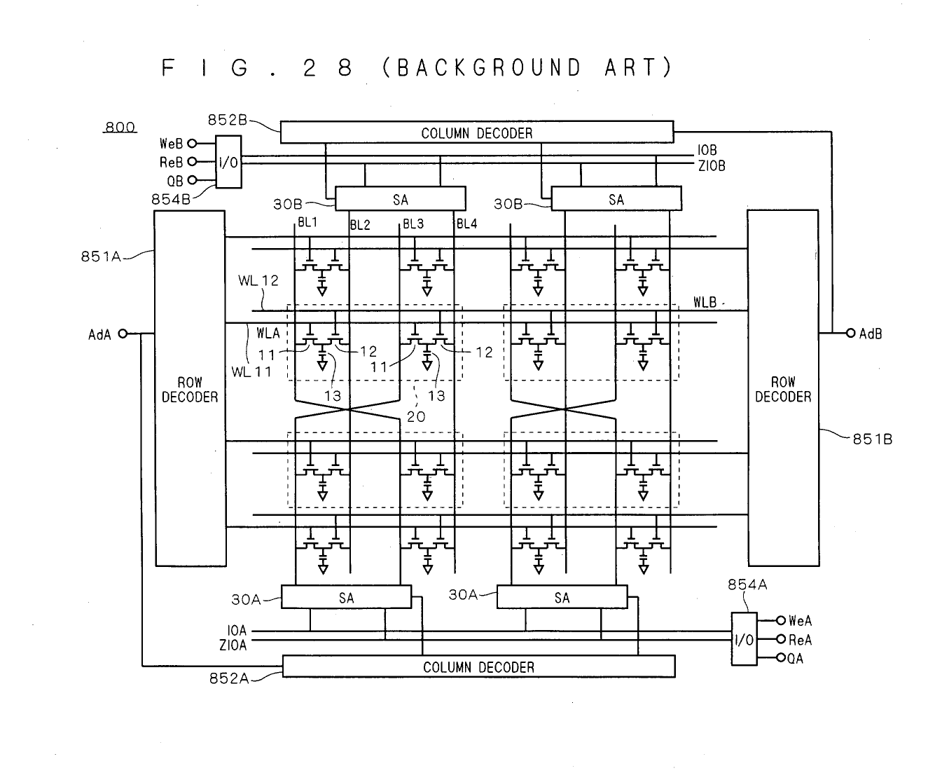

Accordingly, in such a configuration that the connection between the random access memory cells 20 and the bit lines BL1 and BL3 is different from that between the random access memory cells 21 and the bit lines BL1 and BL3 (i.e., bit lines BL1, BL3 are twisted), data (the polarity of data) can agree, regardless of whether access is made by the access circuit 250A or 250B. That is, in the dual port DRAM 200, the polarity of input/output data is independent of the access port, unlike the conventional dual port DRAM 800 (see FIG. 28).

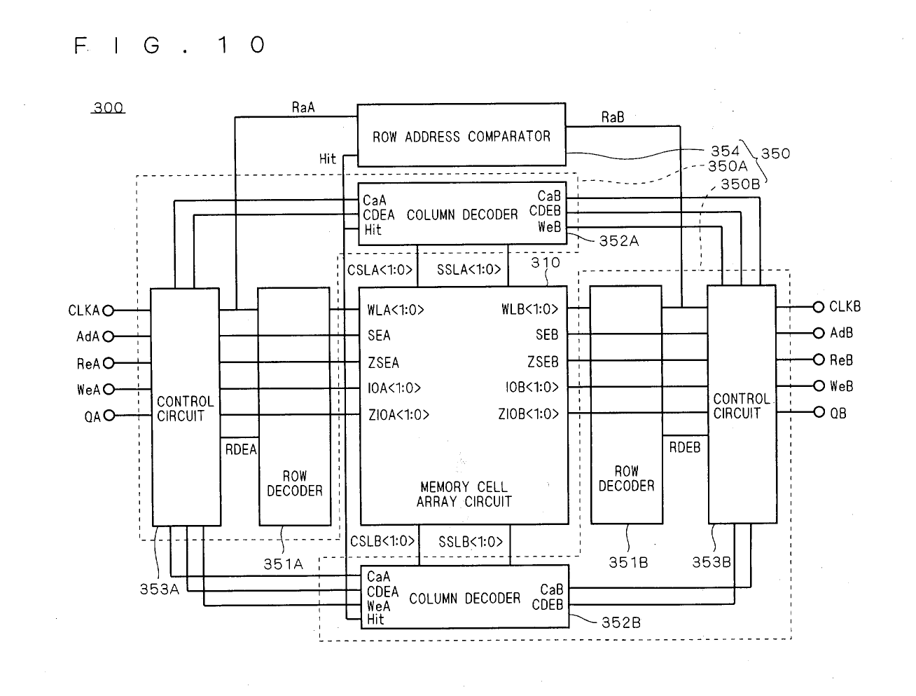

FIG. 9 shows an example of the data inverter 255. In the data inverter 255, a circuit 2551 for input (or for write) and a circuit 2552 for output (or for read) are connected in parallel between input/output control circuits 2553 and 2554. Both of the circuits 2551 and 2552 have a path through which input data is outputted without inverting, and a path through which input data is inverted and outputted. A selector or analog switch is connected in the both paths. These two selectors alternatively enter the on state according to the address AdA.

For example, when row addresses “00”, “01”, “10”, and “11” are appended to dual port DRAM cells 20 locating in four rows from top to bottom in FIG. 7, the bit lines BL1 and BL3 are twisted between the row addresses “01” and “10”. In this instance, it can be judged whether data inversion is required or not by a high order 1 bit of the row address. Therefore, the data inverter 255 of FIG. 9 uses a high order 1 bit of the row address as the address signal AdA. That is, the two selectors can alternatively enter the on state by complementarily using the address signal AdA and its inverted signal as a control signal of the two selectors.

The data inverter 255 is equivalent to a circuit that performs an exclusive OR operation of inputted data and address AdA and outputs the result.

Returning to FIG. 7, the access circuit 250B includes a row decoder 251B, column decoder 252B, and input/output circuit 254B.

The row decoder 252B, which is connected to word lines WL12, receives address AdB of a dual port DRAM cell 20 as access object, and applies a word line activation signal WLB to a predetermined word line WL12. The column decoder 252B, which is connected to sense amplifiers 30B, receives address AdB of the dual port DRAM cell 20 as access object, and outputs a column selection signal CSLB to a predetermined sense amplifier 30B. Thereby, the access circuit 250B performs data reading and writing to the dual port DRAM cell 20 via the bit lines BL2 and BL4.

The input/output circuit 254B is connected to signal lines of data IOB and ZIOB, while it is connected to the terminals of read enable signal ReB, write enable signal WeB, and input/output data QB.

Third Preferred Embodiment

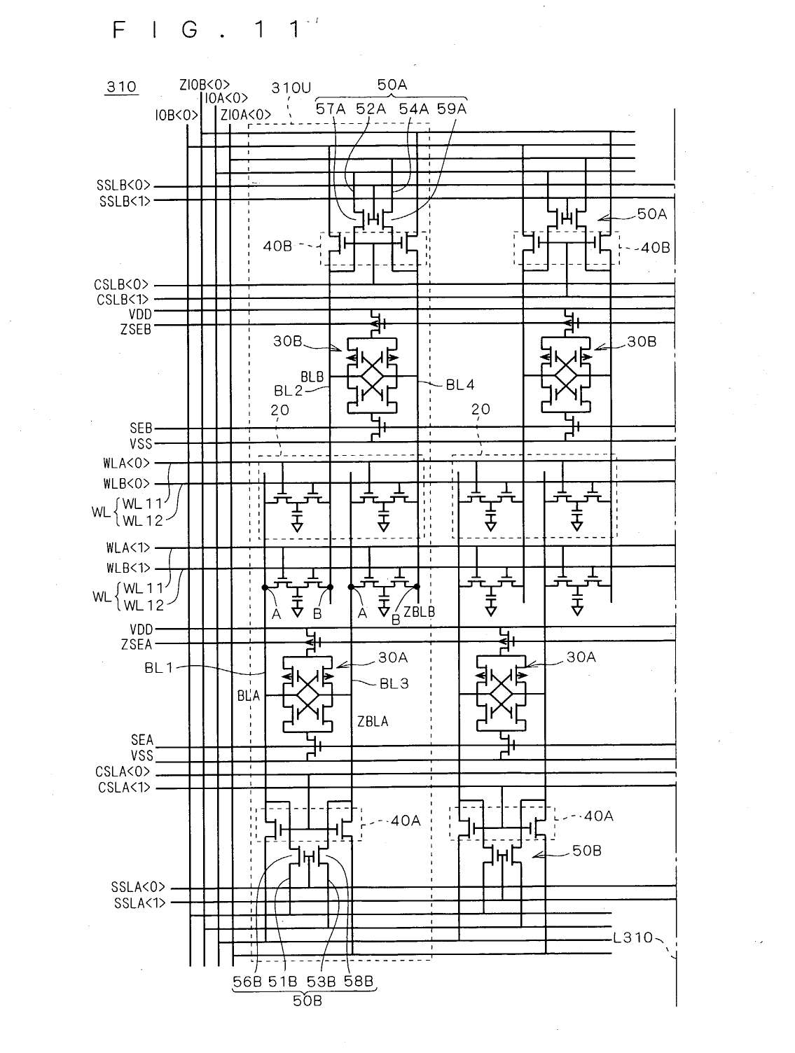

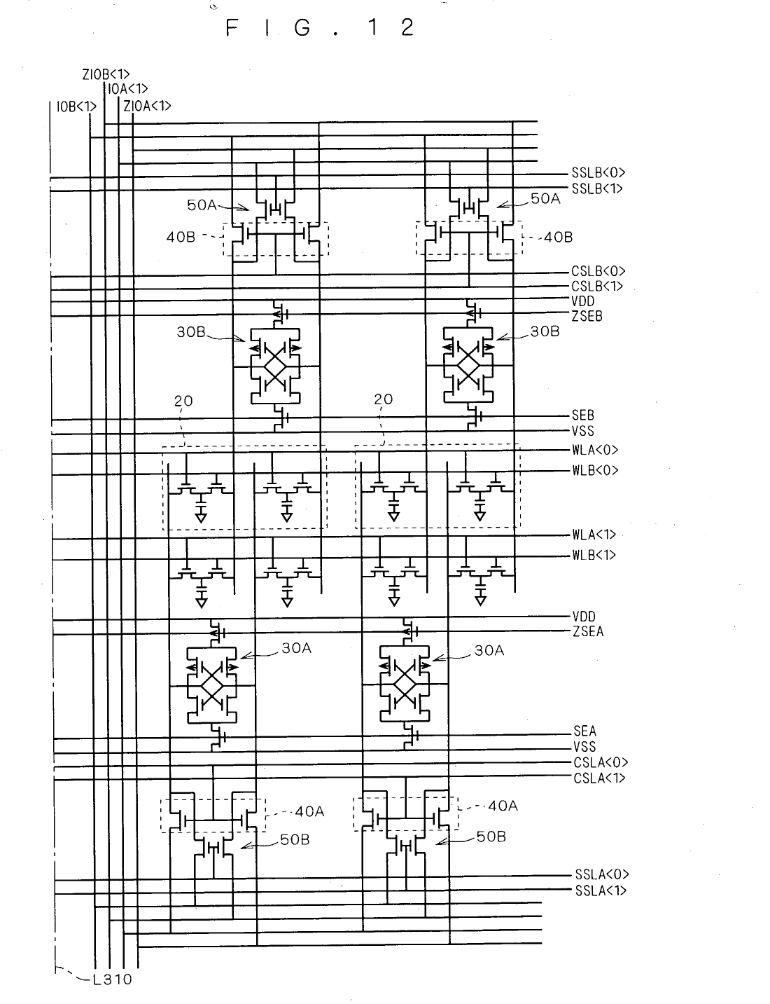

FIG. 10 is a block diagram to explain a dual port DRAM 300 as a semiconductor storage device according to a third preferred embodiment. FIGS. 11 and 12 are circuit diagrams to explain a memory cell array circuit 310 of the dual port DRAM 300. FIGS. 11 and 12 are continuous with a partition line L310.

Referring to FIG. 10, the dual port DRAM 300 is roughly classified into the memory cell array circuit 310 and a peripheral circuit 350 connected to the memory cell array circuit 310. The peripheral circuit 350 includes two access circuits 350A and 350B, and a row address comparator (or judgment circuit) 354. Both of the access circuits 350A and 350B are accessible to individual dual port DRAM cells 20 (see FIG. 11) in the memory cell array circuit 310.

The memory cell array circuit 310 will be described by referring to FIGS. 11 and 12. In FIGS. 11 and 12, the memory cell array circuit 310 includes, for example, four unit circuits 310U. The unit circuit 310U includes a dual port DRAM cell 20, sense amplifiers 30A and 30B, bit lines BL1, BL2, BL3, and BL4, a word line group WL (including word lines WL11 and WL12), column selection circuits 40A and 40B, and write support circuits 50A and 50B. In the following, the dual port DRAM cell 20 will be described by also referring to FIG. 8.

In the unit circuit 310U, access transistors 11 and 12 in one memory cell 10P of the dual port DRAM cell 20 are connected in series between the bit lines BL1 and BL2, and access transistors 11 and 12 in the other memory cell 10Q are connected in series between the bit lines BL3 and BL4. Both of the gates (or control terminals) of the two access transistors 11 of the dual port DRAM cell 20 are connected to the word line WL11 of the word line group WL, and both of the gates of the two access transistors 12 are connected to the word line WL12 of the word line group WL. In the unit circuit 310U, all the dual port DRAM cells 20 are similarly connected to the bit lines BL1, BL2, BL3, and BL4.

FIGS. 11 and 12 illustrate the case that the individual unit circuits 310U include two dual port DRAM cells 20. For the sake of convenience, reference symbol <0> or <1> is appended to the end of reference characters in order to distinguish the word line activation signal WLA for each dual port DRAM cell 20. For example, the expression “WLA<1:0>” means “WLA<0> and WLA<1>”. This expression manner is also employed in other reference characters.

In an alternative, the individual unit circuits 310U may be configured so as to include one or not less than three dual port DRAM cells 20.

The bit lines BL1 and BL3 are connected to the sense amplifier 30A so as to make the so-called folded-bit-line configuration. Likewise, the bit lines BL2 and BL4 are connected to the sense amplifier 30B so as to make the folded-bit-line configuration. FIGS. 11 and 12 show the sense amplifiers 30A and 30B that are configured by a flip-flop circuit. This flip-flop circuit is connected between supply potentials VSS and VDD (>VSS). Sense amplifier activation signals SEA and ZSEA control whether the sense amplifier 30A is to be connected to the supply potentials VSS and VDD. Sense amplifier activation signals SEB and ZSEB control whether the sense amplifier 30B is to be connected to the supply potentials VSS and VDD.

Thus, since the sense amplifiers 30A and 30B are configured by the flip-flop, a complementary relationship holds between data BLA and ZBLA on the bit lines BL1 and BL3, and a complementary relationship holds between data BLB and ZBLB on the bit lines BL2 and BL4.

Hereat, both ports A of the memory cells 10P and 10Q are called under the general term of “a first port”, and both ports B of the memory cells 10P and 10Q are called under the general term of “a second port.” Both gates of the access transistors 11 of the memory cells 10P and 10Q are called under the general term of “a first control terminal,” and both gates of the access transistors 12 of the memory cells 10P and 10Q are called under the general term of “a second control terminal.” To borrow these terms, it can be said “the dual port DRAM cell 20 has the first and second ports and the first and second control terminals that control accesses via the first and second ports, respectively.”

Further, when the bit lines BL1 and BL3 are called under the general term of “a first bit line” and the bit lines BL2 and BL4 are called under the general term of “a second bit line,” the first and second bit lines are connected to the first and second ports, respectively. The first and second control terminals of the dual port DRAM cell 20 are connected to the (first and second) word lines WL11 and WL12, respectively. The (first and second) sense amplifiers 30A and 30B are connected to the first and second bit lines, respectively.

In the unit circuit 110U, as switching elements, MOSFETs are connected in the bit lines BL1 and BL3, respectively, and a column selection signal CSLA is applied to both of the gates of these two MOSFETs. That is, these MOSFETs configure a column selection circuit 40A that controls whether the access circuit 350A is to access to the port A via the bit lines BL1 and BL3. Likewise, as switching elements, MOSFETs are connected in the bit lines BL2 and BL4, respectively. These two MOSFETs configure a column selection circuit 40B that controls whether the access circuit 350B is to access to the port B via the bit lines BL2 and BL4. A column selection signal CSLB is applied to both of the gates of these MOSFETs for the column selection circuit 40B.

Signal lines 52A and 54A branch off of paths between the sense amplifier 30B and column selection circuit 40B on the bit lines BL2 and BL4, respectively. The signal lines 52A and 54A are connected to the bit lines BL2 and BL4 and the signal lines of signals IOA and ZIOA, respectively. Switching elements 57A and 59A that are for example composed of an MOSFET are connected in the signal lines 52A and 54A. A column selection signal SSLB is applied to both gates of the two MOSFETs. At this time, a write support circuit 50A for the access circuit 350A is configured by the signal lines 52A and 54A (to be called “a first signal line” under general term), and switching elements 57A and 59A (to be called “a first switching element” under general term).

On the other hand, signal lines 51B and 53B branch off of paths between the sense amplifier 30A and column selection circuit 40A on the bit lines BL1 and BL3, respectively. The signal lines 51B and 53B are connected to the bit lines BL1 and BL3 and the signal lines of signals IOB and ZIOB, respectively. Switching elements 56B and 58B that are for example composed of an MOSFET are connected in the signal lines 51B and 53B. A column selection signal SSLA is applied to both gates of the two MOSFETs. At this time, a write support circuit 50B for the access circuit 350B is configured by the signal lines 51B and 58B (to be called “a second signal line” under general term), and switching elements 56B and 59B (to be called “a second switching element” under general term).

At this time, by the write support circuit 50A, the access circuit 350A is accessible to the dual port DRAM cell 20 via the bit lines BL2 and BL4. Likewise, by the write support circuit 50B, the access circuit 350B is accessible to the dual port DRAM cell 20 via the bit lines BL1 and BL3.

Referring to FIGS. 11 and 12, the memory cell array circuit 310 is divided into two blocks, each including two unit circuits 310U, for example. The memory cell array circuit 310 is configured such that different column selection signals CSLA<0>, CSLA<1>, CSLB<0>, and CSLB<1> are applied to column selection circuits 40A and 40B in a single block, and such that different column selection signals SSLB<0>, SSLB<1>, SSLA<0>, and SSLA<1> are applied to write support circuits 50A and 50B in a single block. Therefore, the circuits 40A, 40B, 50A, and 50B, all of which belong to a single block, are configured such that they can independently be activated (controlled). It is allowed that the column selection signals CSLA, CSLB, SSLA, and SSLB are shared (overlapped) between different blocks.

Irrespective of block division, the word lines WL11 of the corresponding dual port DRAM cells 20 between the unit circuits 310U are connected together, and sense amplifier activation signals SEA and ZSEA are applied in common to the sense amplifiers 30A between the unit circuits 310U. These are true for the word lines WL12 and the sense amplifiers 30B. Signal lines of the signals IOA, ZIOA, IOB, and ZIOB are provided per block.

Returning to FIG. 10, the access circuit 350A includes a row decoder 351A, column decoder 352A, and control circuit 353A. The access circuit 350B includes a row decoder 351B, column decoder 352B, and control circuit 353B. Generations, inputs and outputs of various signals in the dual port DRAM 300 are basically the same as those in the above-mentioned dual port DRAM 100. However, the dual port DRAM 300 performs a peculiar operation due to differences in configuration.

In particular, the peripheral circuit 350 of the dual port DRAM 300 includes a row address comparator (or judgment circuit) 354, and the access circuits 350A and 350B perform write operation using a row address comparison result signal Hit to be outputted from the row address comparator 354.

More specifically, the row address comparator 354 acquires information of dual port DRAM cells 20 that are access objects of the access circuits 350A and 350B (i.e., row address signals RaA and RaB), and compares the addresses (signals) RaA and RaB. In other words, the row address comparator 354 judges whether the two dual port DRAM cells 20 that are access objects are connected to the same word line group WL, and outputs the comparison result, as row address comparison result signal Hit, to the access circuits 350A and 350B, more specifically, the row decoders 352A and 352B. For example, the row address comparator 354 outputs “1” (or “High”) as signal Hit, when the row addresses RaA and RaB are the same, and outputs “0” (or “Low”) as signal Hit when they are not the same.

Then, when the row address comparator 354 judges that the two access-object cells 20 have the same row address, that is, the both cells 20 are connected to the same word line group WL, the access circuit 350A performs writing operation via not only bit lines BL1 and BL3 but also signal lines 52A and 54A, by bringing switching elements 57A and 59A of the write support circuit 50A into the on state (this on-control is executed by the access circuit 350B) when data is written onto the access object cell 20. In such a case, the access circuit 350B also performs write operation via not only bit lines BL2 and BL4 but also signal lines 51B and 53B.

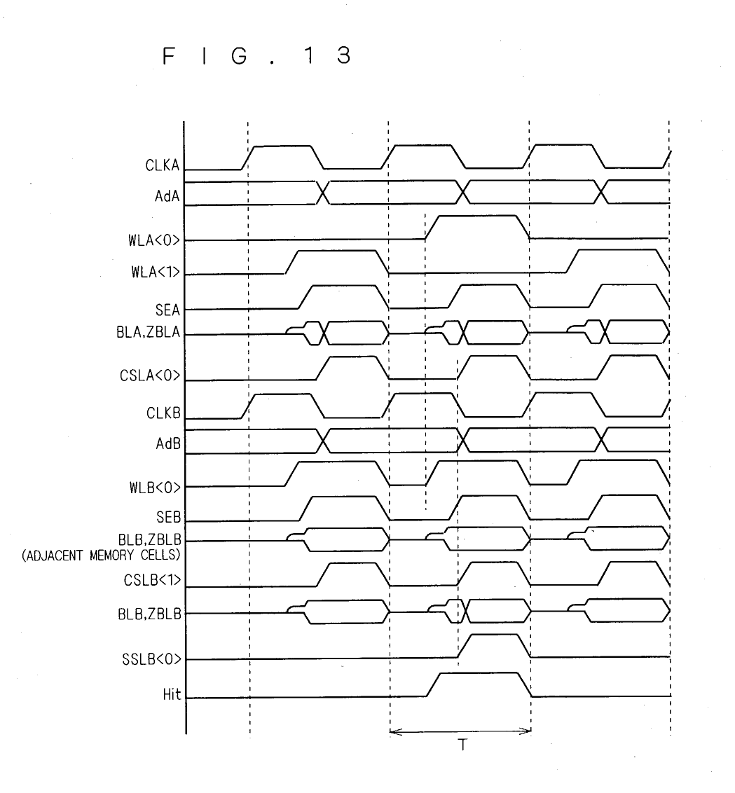

These write operations of the access circuits 350A and 350B are implemented by column selection signals CSL and SSL. Referring to the timing chart of FIG. 13, the following is the case that the access circuit 350A writes data onto one dual port DRAM cell 20 connected to a word line group WL to which word line activation signals WLA<0> and WLB<0> are applied and, at the same time, the access circuit 350B reads data from the other dual port DRAM cell 20 connected to the same word line group WL.

In this case, the word line activation signals WLA<0> and WLB<0> are concurrently applied to the word lines WL11 and WL12, so that data of the aforesaid one dual port DRAM cell 20 is amplified by the corresponding sense amplifier 30A, and the data of the aforesaid the other dual port DRAM cell 20 is amplified by the corresponding sense amplifier 30B. With the above-mentioned configuration of the memory cell array circuit 310, both of sense amplifier activation signals SEA and ZSEA are concurrently applied to the respective sense amplifiers 30A connected to the above two dual port DRAM cells 20. This is true for the respective sense amplifiers 30B. As the result, the sense amplifiers 30B and 30A that are paired with the aforesaid sense amplifiers 30A and 30B, respectively, are also activated so that the data of the dual port DRAM cell 20 is also inputted to these sense amplifiers 30B and 30A.

Thereafter, by the column selection signal CSLB<1>, the data of the aforesaid the other dual port DRAM cell 20 is read out as data IOB and ZIOB to the exterior via a column selection circuit 40B and the bit lines BL2 and BL4. On the other hand, by the column selection signal CSLA<0>, the data of the aforesaid one dual port DRAM cell 20 is written onto the sense amplifier 30A via a column selection circuit 40A and the bit lines BL1 and BL3.

At this time, when the write data is different from the data read and held immediately before that, the data of the sense amplifiers 30A and 30B to be paired in the unit circuit 310U collide via the dual port DRAM cell 20 (i.e., normal write operation cannot be executed and the complementary relationship does not hold).

To overcome this, in the dual port DRAM 300, as shown in period T in FIG. 13, the column selection signal CSLA<0> activates the column selection circuit 40A and, at the same time, the column selection signal SSLB<0> activates the write support circuit 50A. The access circuit 350A writes data onto the sense amplifier 30A via the column selection circuit 40A and bit lines BL1 and BL3, and also writes the same data onto the sense amplifier 30B via the write support circuit 50A (in other words, signal lines 52A and 54A) and bit lines BL2 and BL4. Thus, data collision via the write-object cells 20 by performing write operation from both of the ports A and B.

In the case that the access circuit 350B performs writing, when both of the access object cells 20 are connected to the same word line group WL, the write support circuit 50B is used to perform write operation via signal lines 51B and 53B and bit lines BL1 and BL3.

Similar operation is to be executed when both of the access circuits 350A and 350B perform writing.

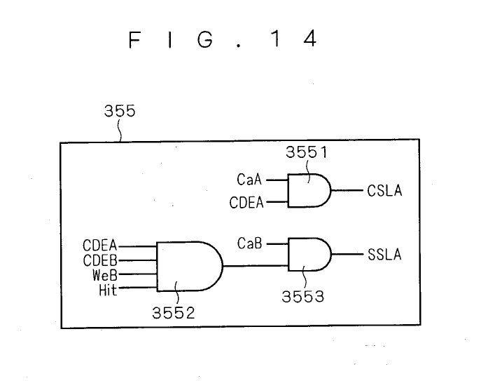

FIG. 14 shows an example of signal generation circuit 355 for generating column selection signals CSLA and SSLA. The signal generation circuit 355 performs an AND operation of a column address signal CaA and a column selection line activation signal CDEA, by an AND circuit 3551, and outputs the result as column selection signal CSLA. On the other hand, the signal generation circuit 355 performs an AND operation of column selection signals CDEA and CDEB, write enable signal WeB, and row address comparison result signal Hit, by an AND circuit 3552. The signal generation circuit 355 performs an AND operation of the result obtained in the circuit 3552 and a column address signal CaB, by an AND circuit 3553, and outputs this result as column selection signal SSLA. The signal generation circuit 355 for the above-mentioned column selection signals CSLA and SSLA is disposed in the column decoder 352A. Likewise, a signal generation circuit 355 disposed in the column decoder 352B can generate column selection signals CSLB and SSLB.

Fourth Preferred Embodiment

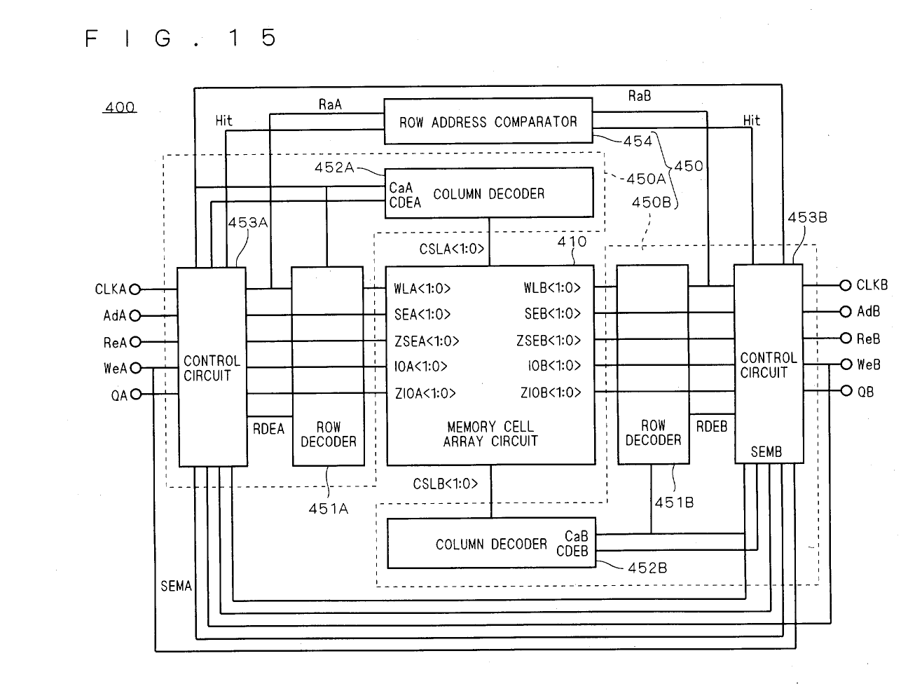

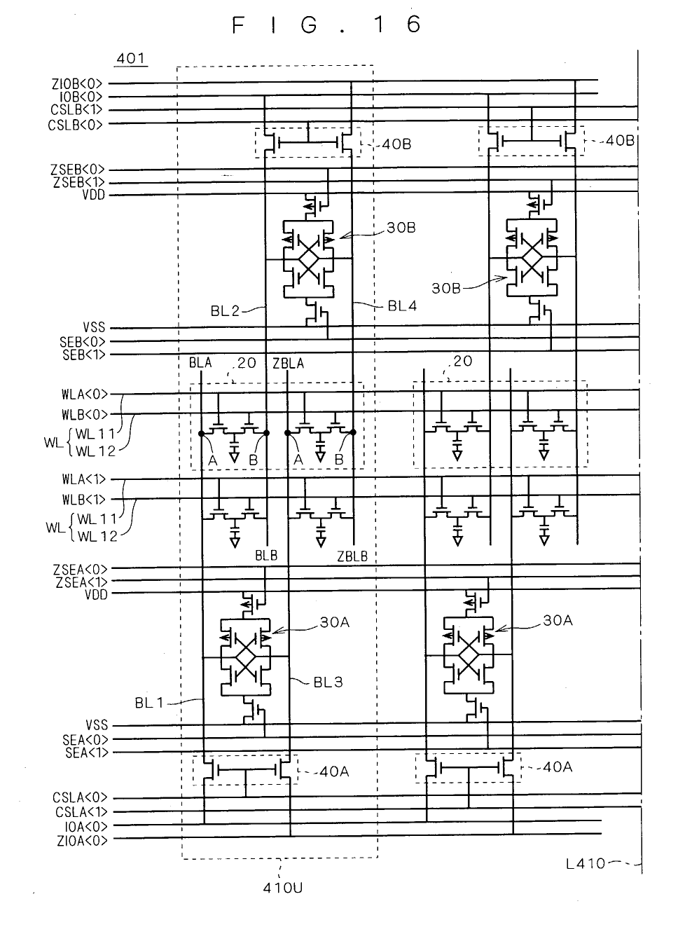

FIG. 15 is a block diagram to explain a dual port DRAM 400 as a semiconductor storage device according to a fourth preferred embodiment. FIGS. 16 and 17 are circuit diagrams to explain a memory cell array circuit 410 of the dual port DRAM 400. FIGS. 16 and 17 are continuous with a partition line L410.

Referring to FIG. 15, the dual port DRAM 400 is roughly classified into the memory cell array circuit 410 and a peripheral circuit 450 connected to the memory cell array circuit 410. The peripheral circuit 450 includes two access circuits 450A and 450B, and a row address comparator (or judgment circuit) 454. Both of the access circuits 450A and 450B are accessible to individual dual port DRAM cells 20 (see FIG. 16) in the memory cell array circuit 410.

The memory cell array circuit 410 and its unit circuit 410U shown in FIGS. 16 and 17 have basically the same configuration as the memory cell array circuit 310 and its unit circuit 310U shown in FIGS. 11 and 12, except that the write support circuits 50A and 50B are not used.

The memory cell array circuit 410 is divided into two blocks, each including two unit circuits 410U, for example. Unlike the memory cell array circuit 310, the memory cell array circuit 410 is configured such that different sense amplifier activation signals SEA<0>, ZSEA<0>, SEA<1>, and ZSEA<1> are applied to the individual sense amplifiers 30A in a single block, and such that different sense amplifier activation signals SEB<0>, ZSEB<0>, SEB<1>, and ZSEB<1> are applied to the individual sense amplifiers 30B in a single block. Therefore, it is configured such that the sense amplifiers 30A and 30B that belong to a single block are independently activated (controlled). It is allowed that the sense amplifier activation signals SEA, ZSEA, SEB, and ZSEB are shared (overlapped) between different blocks.

Returning to FIG. 15, the access circuit 450A includes a row decoder 451A, column decoder 452A, and control circuit 453A. The access circuit 450B includes a row decoder 451B, column decoder 452B, and control circuit 453B. Generations, inputs and outputs of the various signals in the dual port DRAM 400 are basically the same as those in the above-mentioned dual port DRAM 100. However, the dual port DRAM 400 performs a peculiar operation due to differences in configuration.

In particular, the peripheral circuit 450 of the dual port DRAM 400 includes a row address comparator (or judgment circuit) 454, and the access circuits 450A and 450B perform write operation using a row address comparison result signal Hit to be outputted from the row address comparator 454.

More specifically, like the row address comparator 354 (see FIG. 10), the row address comparator 454 compares row address signals RaA and RaB, and judges whether access-object two dual port DRAM cells 20 are connected to the same word line group WL. Then, the row address comparator 454 outputs the comparison result, as row address comparison result signal Hit, to the access circuits 450A and 450B, more specifically, the control circuits 453A and 453B.

When the row address comparator 454 judges that the two access-object cells 20 have the same row address, that is, the both cells 20 are connected to the same word line group WL, the access circuit 450B deactivates a sense amplifier 30B (or write support circuit) connected to write-object cell 20, when the access circuit 450A performs write operation to the access-object cell 20. That is, the access circuit 450B deactivates the sense amplifier 30B connected to bit lines BL2 and BL4, which are connected to the write-object cell 20 but not used for write operation by the access circuit 450A. Similarly, when the access circuit 450B performs write operation, the access circuit 450A deactivates the sense amplifier 30A (or write support circuit) connected to the write-object cell 20.

These write operations of the access circuits 450A and 450B are implemented by sense amplifier activation signals SEA, ZSEA, SEB, and ZSEB. Like the third preferred embodiment, the following is the case that the access circuit 450A writes data to one dual port DRAM cell 20 connected to a word line group WL (i.e., word lines WL11 and WL12), to which word line activation signals WLA<0> and WLB<0> are applied and, at the same time, the access circuit 450B reads out data from the other dual port DRAM cell 20 connected to the same word line group WL.

At this time, as previously described in the third preferred embodiment, when the write data are different before and after writing, the data of the sense amplifiers 30A and 30B collide via the write-object cells 20.

To overcome this, in the dual port DRAM 400, the control circuit 453B deactivates the sense amplifier activation signals SEB<0> and ZSEB<0>, in order to deactivate the sense amplifier 30B connected to port B of the aforesaid one dual port DRAM cell 20 as the write-object. This prevents data collision via the write-object cells 20.

The operation of deactivating the sense amplifier connected to the port on the side that is not accessed at the time of writing is also applicable when the access circuit 450B performs writing or when both of the access circuits 450A and 450B perform writing.

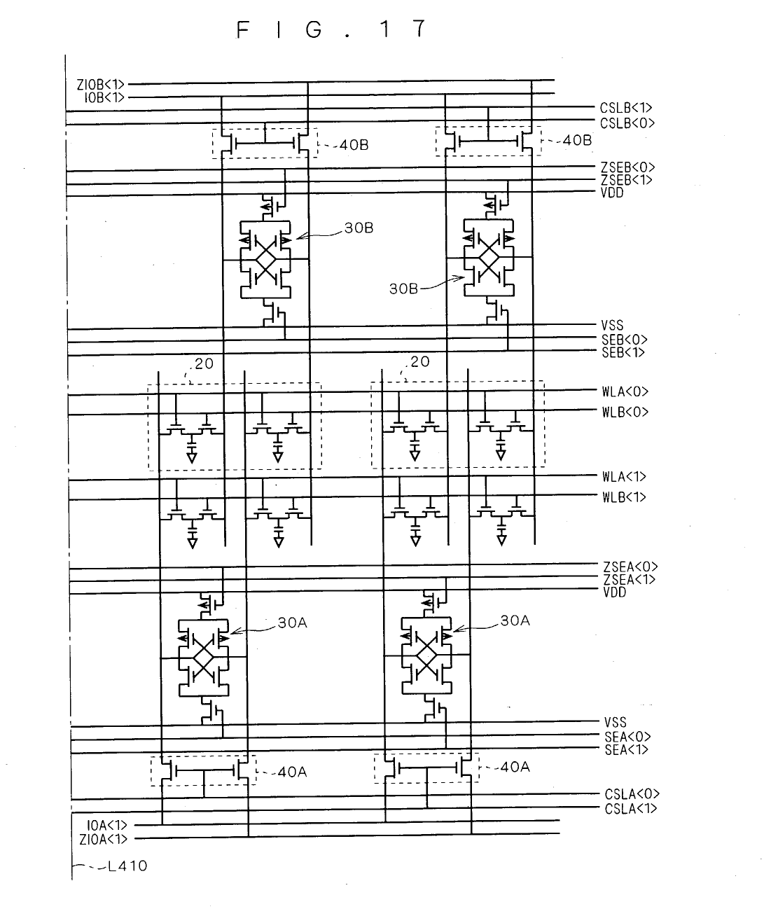

FIG. 18 shows an example of signal generation circuit 455 for generating sense amplifier activation signals SEA and ZSEA. The signal generation circuit 455 performs an AND operation of a sense amplifier activation signal SEMB (to be generated in the control circuit 453B), a write enable signal WeB, and a row address comparison result signal Hit, by an AND circuit 4551. The signal generation circuit 455 performs an NAND operation of the result obtained in the AND circuit 4551 and a column address signal CaB<0>, by an NAND circuit 4552. The signal generation circuit 455 performs an AND operation of the result of the NAND operation and a sense amplifier activation signal SEMA (to be generated in the control circuit 453A), by an AND circuit 4553, and outputs the result as a sense amplifier activation signal SEA<0>. On the other hand, this result is inverted by an NOT circuit 4554 to output as a sense amplifier activation signal ZSEA<0>. A similar sense amplifier activation signal generation circuit 455 can generate sense amplifier activation signals SEA<1>, ZSEA<1>, SEB<0:1>, and ZSEB<0:1>. The signal generation circuit 455 for generating the sense amplifier activation signals SEA and ZSEA and that for generating the sense amplifier activation signals SEB and ZSEB are disposed in the control circuits 453A and 453B, respectively.

Fifth Preferred Embodiment

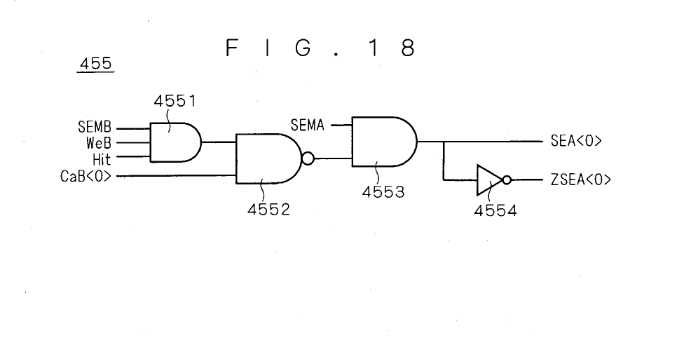

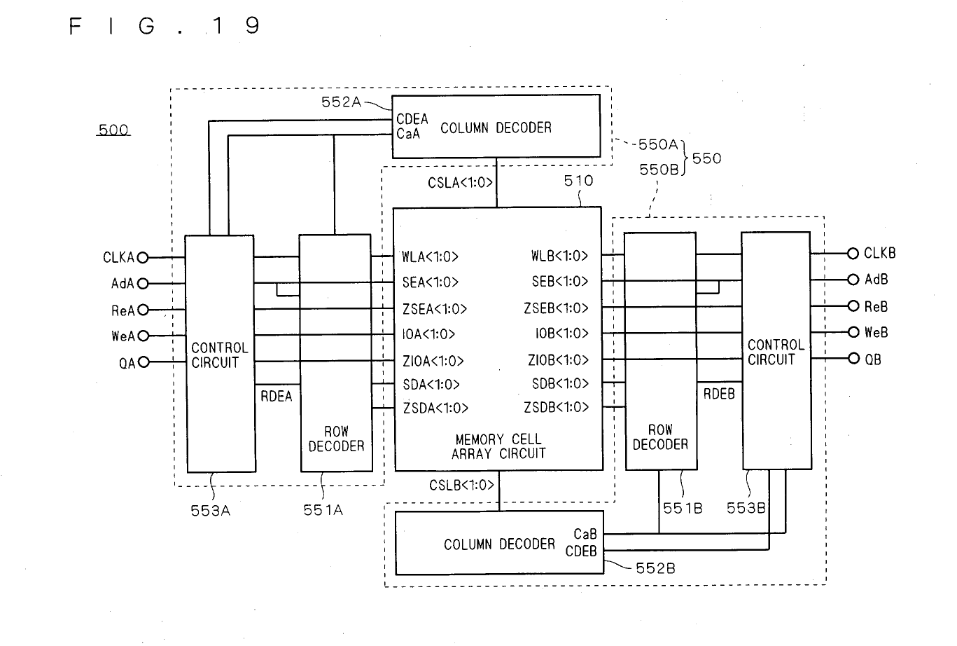

FIG. 19 is a block diagram to explain a dual port DRAM 500 as a semiconductor storage device according to a fifth preferred embodiment. FIGS. 20 and 21 are circuit diagrams to explain a memory cell array circuit 510 of the dual port DRAM 500. FIGS. 20 and 21 are continuous with a partition line L510.

Referring to FIG. 19, the dual port DRAM 500 is roughly classified into the memory cell array circuit 510 and a peripheral circuit 550 connected to the memory cell array circuit 510. The peripheral circuit 550 includes two access circuits 550A and 550B. Both of the access circuits 550A and 550B are accessible to individual dual port DRAM cells 20 (see FIG. 20) in the memory cell array circuit 510. Generations, inputs and outputs of various signals in the dual port DRAM 500 are basically the same as those in the above-mentioned dual port DRAM 100. However, the dual port DRAM 500 performs a peculiar operation due to differences in configuration.

The unit circuit 510U of the memory cell array circuit 510 shown in FIGS. 20 and 21 has basically the same configuration as the unit circuit 410U shown in FIGS. 16 and 17.

The memory cell array circuit 510 is divided into two blocks, each including two unit circuits 510U and one row selection circuit 555. Unlike the memory cell array circuit 410, both of sense amplifier activation signals SEA and ZSEA are applied to all the sense amplifiers 30A in a single block. This is true for the sense amplifiers 30B. Further, all the column selection circuits 40A in a single block are controlled by a column selection signal CSLA. This is true for the column selection circuit 40B. It is noted that the sense amplifier activation signals SEA, ZSEA, SEB, and ZSEB and the column selection signals CSLA and CSLB are provided per block.

In the memory cell array circuit 510, the word lines WL11 and WL12 (i.e., word line group WL) of the corresponding dual port DRAM cell 20 among a plurality of unit circuits 510U that belong to a single block are connected together, whereas the word line groups WL are not connected to each other between the blocks.

In the individual blocks, the respective word line groups WL (namely, the word lines WL11 and WL12) are connected to this row selection circuit 555. The row selection circuit 555 is configured such that only when an access-object cell 20 of the access circuit 550A is present in a block to which this row selection circuit 555 belongs, a word line activation signal WLa is selectively applied to the word line WL11 of the access-object cell 20. The row selection circuit 555 is also configured such that when an access-object cell 20 of the access circuit 550B is present in a block, a word line activation signal WLb is selectively applied to the word line WL12 of the access-object cell 20.

According to the dual port DRAM 500, the word line groups WL can be activated per block. Therefore, when the access circuits 550A and 550B access to dual port DRAM cells 20 that belong to different blocks, such data collision as in the third preferred embodiment does not occur.

Concretely, as shown in FIGS. 20 and 21, the row selection circuit 555 includes AND circuits 555A, each connected to the corresponding word line WL11, and AND circuits 555B, each connected to the corresponding word line WL12.

The AND circuit 555A performs an AND operation of an inverted signal of a word line activation signal ZWLA holding a complementary relationship with a word line activation signal WLA, a row selection circuit activation signal SDA, and an inverted signal of a row selection circuit activation signal ZSDA. Then, the AND circuit 555A outputs the operation result to the word line WL11, as a word line activation signal WLa. The row selection circuit activation signals SDA and ZSDA hold a complementary relationship.

Likewise, the AND circuit 555B performs an AND operation of an inverted signal of a word line activation signal ZWLB holding a complementary relationship with a word line activation signal WLB, a row selection circuit activation signal SDB, and an inverted signal of a row selection circuit activation signal ZSDB. Then, the AND circuit 555B outputs the operation result to the word line WL12, as a word line activation signal WLb. The row selection circuit activation signals SDB and ZSDB hold a complementary relationship.

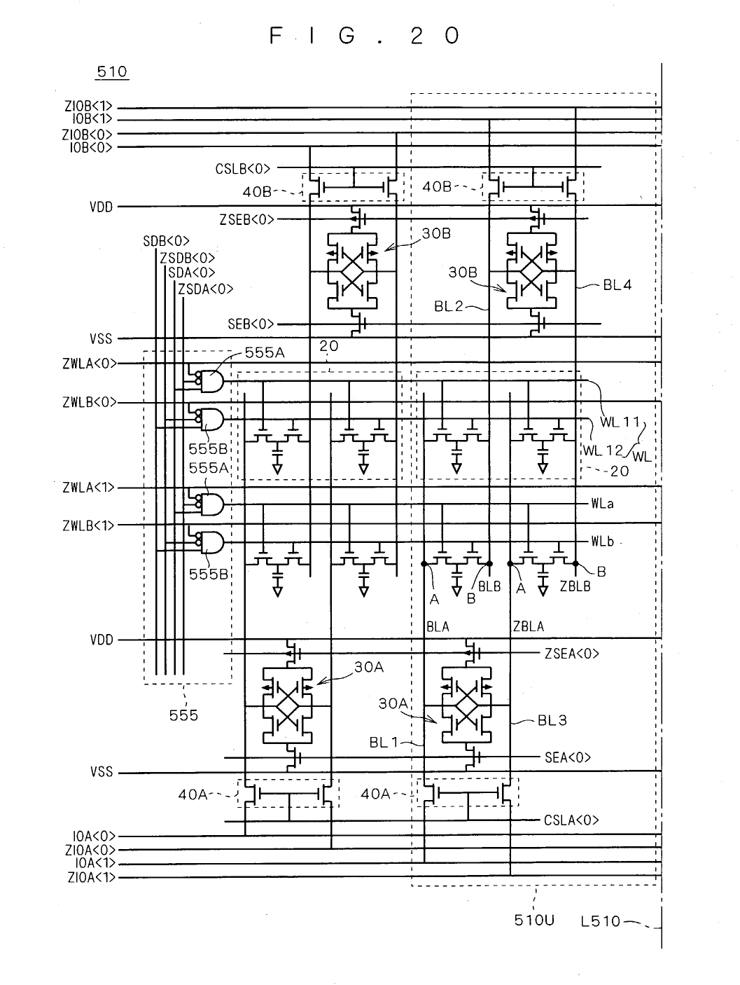

The above-mentioned row selection circuit activation signals SDA and ZSDA are generated by the signal generation circuit 556 exemplified in FIG. 22. Specifically, the signal generation circuit 556 performs an AND operation of a word line activation signal RDEA and a column address signal CaA<0> by an AND circuit 5561, and outputs the operation result as a row selection circuit activation signal SDA<0>. Further, the signal generation circuit 556 inverts this operation result by an NOT circuit 5562 to output as a row selection circuit activation signal ZSDA<0>. A similar signal generation circuit 556 can generate row selection circuit activation signals SDA<1> and ZSDA <1>. The signal generation circuit 556 for generating the row selection circuit activation signals SDA<0:1> and ZSDA<0:1> is disposed in the row decoder 551A. A similar signal generation circuit 556 disposed in the row decoder 251B can generate row selection circuit activation signals SDB <0:1> and ZSDB <0:1>.

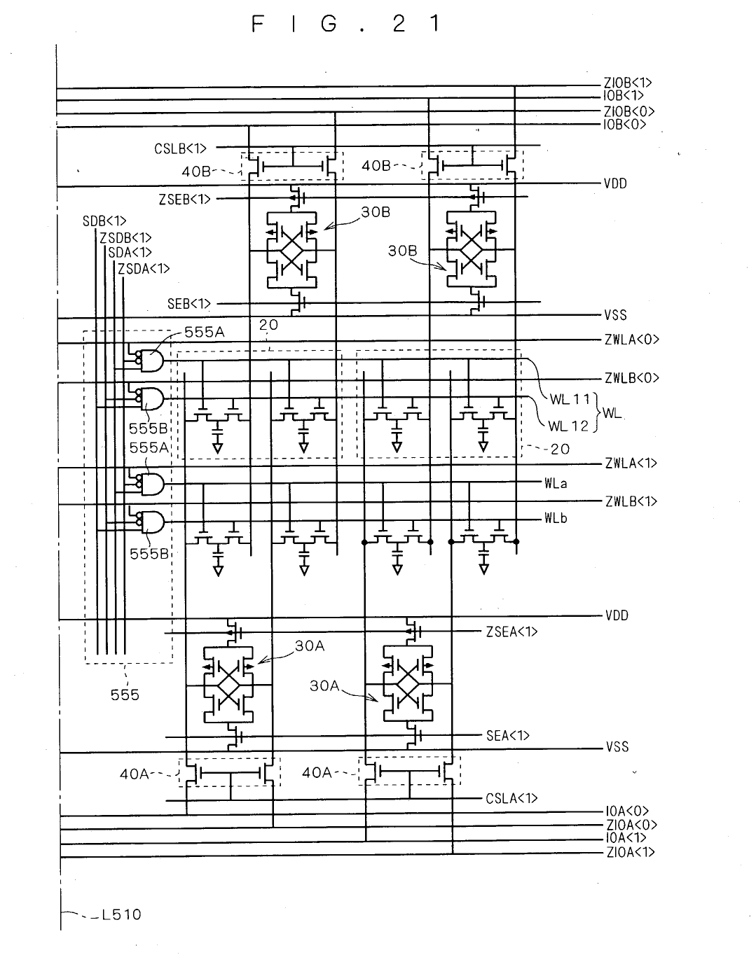

The above-mentioned sense amplifier activation signals SEA and ZSEA are generated by the signal generation circuit 557 exemplified in FIG. 23. Specifically, the signal generation circuit 557 performs an AND operation of a sense amplifier activation signal SEMA<0> (to be generated in the control circuit 553A) and a column address signal CaA<0> by an AND circuit 5571, and outputs the result as a sense amplifier activation signal SEA<0>. Further, the signal generation circuit 557 inverts this operation result by an NOT circuit 5572 to output as a sense amplifier activation signal ZSEA<0>. A similar signal generation circuit 557 can generate sense amplifier activation signals SEA <1>, ZSEA <1>, SEB<0:1>, and ZSEB<0:1>. The signal generation circuit 557 for generating the sense amplifier activation signals SEA<0:1> and ZSEA<0:1> is disposed in the control circuit 553A. The signal generation circuit 557 for generating the sense amplifier activation signals SEB<0:1> and ZSEB<0:1> is disposed in the control circuit 553B.

In an alternative, the memory cell array circuit 510 may be configured such that one or not less than three unit circuits 510U are disposed per block. When each block includes a single unit circuit 510U and selection circuit 555, that is, a selection circuit 555 is disposed per unit circuit 510U, data collision is avoidable over the entire memory cell array circuit 510. In dual port memory, concurrent access to memory cells having the same address is generally prohibited. Therefore, in the case that each block includes a single unit circuit 510U, concurrent activation to word line groups WL having the same row address results in different column addresses. On the other hand, the number of selection circuits 555 can be reduced by disposing a plurality of unit circuits 510U per block, thereby leading to a smaller memory cell array circuit 510.

Modifications of Third to Fifth Preferred Embodiments

In the dual port DRAM 100 (see FIGS. 2 and 3), the memory cell 10 has the first and second ports A and B, and has the gates of the access transistors 11 and 12 as first and second control terminals. The first and second control terminals of the dual port DRAM cell 10 are connected to the first and second word lines WL11 and WL12, respectively. For example, the first and second bit lines BL11 and BL12 are connected to the first and second ports A and B, respectively. The first and second sense amplifiers 30A and 30B are connected to the first and second bit lines BL11 and BL12, respectively.

In the dual port DRAM 200 (see FIGS. 7 and 8), the bit lines BL1 and BL3 twist, while “the first bit line,” which is the general term of the bit lines BL1 and BL3, is connected to the first port A and first sense amplifier 30A.

Since in the dual port DRAM 100, the word line groups are connected in common between the unit circuits 110U, the above-mentioned row address comparator 354 (see FIG. 10) and the write support circuits 50A and 50B (see FIG. 11) are applicable to the dual port DRAM cell 100 (see FIGS. 2 and 7). Likewise, the operation of deactivating the sense amplifier 30A or 30B connected to the bit line that is not used for writing in the dual port DRAM 300 is also applicable to the dual port DRAM cell 100. These are true for the dual port DRAM 200.

The above mentioned row selection circuit 555 (see FIG. 20) is applicable to the dual port DRAM cells 100 and 200, by dividing a plurality of unit circuits 110U and 210U into blocks, as in the case with the dual port DRAM 500.

Modifications of First to Fifth Preferred Embodiments

In an alternative, the access circuit 150B may be used only for read or write operation. For example, if it is used only for reading, the write support circuit 50B (see FIG. 11) may be omitted.

The number of the dual port DRAM cells 10 or 20 in the unit circuits 110U, 210U, 310U, 410U, and 510U, and the number of the unit circuits 110U, 210U, 310U, 410U, and 510U in the dual port DRAMs 100, 200, 300, 400, and 500 are cited merely by way of example and without limitation.

The foregoing first to fifth preferred embodiments are directed to the case that the dual port DRAM cells 10 and 20 have the two ports A and B, i.e., the dual port. It is possible to configure a semiconductor storage device using DRAM cells having three or more ports by modifying the dual port DRAM 100, 200, 300, 400, or 500. The semiconductor storage devices so modified include at least one of the configurations of the dual port DRAMs 100, 200, 300, 400, and 500.

While the invention has been shown and described in detail, the foregoing description is in all aspects illustrative and not restrictive. It is therefore understood that numerous modifications and variations can be devised without departing from the scope of the invention.

What is claimed is:

1. A semiconductor storage device comprising:
a plurality of unit circuits; and
a peripheral circuit connected to said plurality of unit circuits, wherein
each of said plurality of unit circuits includes:
a plurality of first and second sense amplifiers;
a plurality of first and second bit lines connected to said plurality of first and second sense amplifiers, respectively, so as to make an open-bit-line configuration; and
a plurality of random access memory cells, each having first and second access transistors connected in series between paired first and second bit lines, and a capacitor connected to said first and second access transistors,
in said plurality of unit circuits, said plurality of first and second bit lines are alternately disposed,
said peripheral circuit includes:
a first access circuit configured such that reading and writing of data to said plurality of random access memory cells are executable via said plurality of first bit lines; and
a second access circuit configured such that reading and/or writing of data to said plurality of random access memory cells are executable via said plurality of second bit lines,
said first or second access circuit includes a control signal generation circuit configured so as to output a control signal in response to an amplification period in which a first or second sense amplifier amplifies the potential of said first or second bit line, and
said second or first access circuit receives said control signal and operates so as not to change the potential of a second or first bit line connected to said first or second bit line in said amplification period via a random access memory cell.

2. The semiconductor storage device according to claim 1 wherein
said second or first access circuit includes a timing delay circuit configured so as to receive said control signal and delay an operation timing of said second or first access circuit.

3. The semiconductor storage device according to claim 2 wherein
each of said plurality of unit circuits further includes a plurality of first and second word lines connected to the gates of said first and second access transistors, and
said timing delay circuit is configured so as to delay the timing at which there occurs a change in the potential of a second or first word line connected to said random access memory cell to which said first or second bit line in said amplification period is connected.

4. A semiconductor storage device comprising:
a plurality of unit circuits; and
a peripheral circuit connected to said plurality of unit circuits, wherein
each of said plurality of unit circuits includes:
a random access memory cell having first and second ports and first and second control terminals that control accesses via said first and second ports, respectively;
first and second bit lines connected to said first and second ports, respectively, and
a word line group having first and second word lines connected to said first and second control terminals, respectively,
a plurality of word line groups being connected in common among said plurality of unit circuits,
said peripheral circuit includes:
a first access circuit configured such that reading and writing of data to each random access memory cell are executable via said first bit line;
a second access circuit configured such that reading and/or writing of data to said each random access memory cell are executable via said second bit line; and
a judgment circuit which acquires information of access-object cells that become access objects of said first and second access circuits among a plurality of random access memory cells, and which judges whether said access-object cells are connected to the same word line group,
said semiconductor storage device further comprising:
a first write support circuit to be controlled based on the result of judgment made by said judgment circuit when said first access circuit performs said writing of said data, and
if configured such that said second access circuit can execute said writing, said semiconductor storage device further comprising:
a second write support circuit to be controlled based on the result of judgment made by said judgment circuit when said second access circuit performs said writing of said data.

5. The semiconductor storage device according to claim 4 wherein
said second write support circuit includes a first sense amplifier connected to said first bit line,
said first write support circuit includes a second sense amplifier that is connected to said second bit and is activated independently of said first sense amplifier, and
when said access-object cells are connected to said same word line group, said second or first sense amplifier connected to said access-object cell is deactivated when said first or second access circuit performs said writing.

6. The semiconductor storage device according to claim 4 wherein
said first write support circuit includes:
a first signal line branching off of said second bit line; and
a first switching element connected in said first signal line,
said second write support circuit includes:
a second signal line branching off of said first bit line; and
a second switching element connected in said second signal line, and
when said access-object cells are connected to said same word line group, said first or second access circuit performs said writing via not only said first or second bit line but also said first or second signal line, by control of said first or second switching element.

7. A semiconductor storage device comprising:
a plurality of unit circuits; and
a peripheral circuit connected to said plurality of unit circuits, wherein
each of said plurality of unit circuits includes:
a random access memory cell having first and second ports and first and second control terminals that control accesses via said first and second ports, respectively;
first and second bit lines connected to said first and second ports, respectively, and
a word line group having first and second word lines connected to said first and second control terminals, respectively,
said peripheral circuit includes:
a first access circuit configured such that reading and writing of data to each random access memory cell are executable via said first bit line; and
a second access circuit configured such that reading and/or writing of data to said each random access memory cell are executable via said second bit line,
said plurality of unit circuits are divided into a plurality of blocks so as to include at least one unit circuit, said word line groups are not connected in common among said plurality of blocks,
said semiconductor storage device further comprising:
a plurality of selection circuits disposed in said plurality of blocks, respectively, wherein
each of said plurality of selection circuits is configured so as to selectively activate, only when an access-object cell that becomes access object of said first or second access circuit is present in the corresponding block, said first or second word line of said at least one unit circuit in said corresponding block.
